(19) United States
(12) Patent Application Publication
(10) Pub. No.: US 2024/0324179 A1
(43) Pub. Date: Sep. 26, 2024

(54) SEMICONDUCTOR DEVICE AND METHOD OF MANUFACTURING THE SAME

(71) Applicant: Kioxia Corporation, Tokyo (JP)

(72) Inventors: Yusuke MUTO, Yokkaichi Mie (JP); Masaya TODA, Yokkaichi Mie (JP); Yuta SAITO, Yokkaichi Mie (JP); Kazuhiro KATONO, Mie Mie (JP); Akifumi GAWASE, Kuwana Mie (JP); Kota TAKAHASHI, Yokkaichi Mie (JP); Kazuhiro MATSUO, Kuwana Mie (JP); Masaya NAKATA, Yokkaichi Mie (JP); Takuma DOI, Yokkaichi Mie (JP); Kenichiro TORATANI, Fujisawa Kanagawa (JP)

(73) Assignee: Kioxia Corporation, Tokyo (JP)

(21) Appl. No.: 18/599,234

(22) Filed: Mar. 8, 2024

(30) Foreign Application Priority Data
Mar. 20, 2023 (JP) 2023-044186

(51) Int. Cl. H10B 12/00

(52) U.S. Cl. CPC H10B 12/33; H10B 12/05

(57) ABSTRACT

The semiconductor device includes a substrate, an oxide semiconductor layer spaced from the substrate in a first direction intersecting with a surface of the substrate, a first wiring opposed to a part of the oxide semiconductor layer, a gate insulating film disposed between the oxide semiconductor layer and the first wiring, a second wiring electrically connected to one end in the first direction of the oxide semiconductor layer, and a first insulating layer disposed on a surface on one side and a surface on the other side in a second direction intersecting with the first direction of the second wiring. The second wiring contains a first metallic element, and the first insulating layer contains the first metallic element and oxygen (O).

### CROSS-REFERENCE TO RELATED APPLICATIONS

This application is based upon and claims the benefit of Japanese Patent Application No. 2023-044186, filed on Mar. 20, 2023, the entire contents of which are incorporated herein by reference.

### BACKGROUND

### Field

Embodiments described herein relate generally to a semiconductor device and a method of manufacturing the same.

### Description of the Related Art

There has been known a semiconductor device including an oxide semiconductor layer, a first wiring opposed to the oxide semiconductor layer, and a gate insulating film disposed between the oxide semiconductor layer and the first wiring.

### BRIEF DESCRIPTION OF THE DRAWINGS

FIG. 1 is a schematic circuit diagram illustrating a part of a configuration of a semiconductor device according to a first embodiment;

FIG. 2 is a schematic cross-sectional view illustrating a part of the configuration of the semiconductor device;

FIG. 3A is a schematic cross-sectional view illustrating a part of the configuration of the semiconductor device;

FIG. 3B is a schematic cross-sectional view illustrating a part of the configuration of the semiconductor device;

FIG. 4 is a schematic plan view illustrating a part of the configuration of the semiconductor device;

FIG. 5 is a schematic plan view illustrating a part of the configuration of the semiconductor device;

FIG. 6 is a schematic plan view illustrating a part of the configuration of the semiconductor device;

FIG. 7 is a schematic cross-sectional view for describing a method of manufacturing the semiconductor device;

FIG. 8 is a schematic cross-sectional view for describing the method of manufacturing;

FIG. 9 is a schematic cross-sectional view for describing the method of manufacturing;

FIG. 10 is a schematic cross-sectional view for describing the method of manufacturing;

FIG. 11 is a schematic cross-sectional view for describing the method of manufacturing;

FIG. 12 is a schematic cross-sectional view for describing the method of manufacturing;

FIG. 13 is a schematic cross-sectional view for describing the method of manufacturing;

FIG. 14 is a schematic cross-sectional view for describing the method of manufacturing;

FIG. 15 is a schematic cross-sectional view for describing the method of manufacturing;

FIG. 16 is a schematic cross-sectional view for describing the method of manufacturing;

FIG. 17 is a schematic cross-sectional view for describing the method of manufacturing;

FIG. 18 is a schematic cross-sectional view for describing the method of manufacturing;

FIG. 19 is a schematic cross-sectional view for describing the method of manufacturing;

FIG. 20 is a schematic cross-sectional view for describing the method of manufacturing;

FIG. 21 is a schematic cross-sectional view for describing the method of manufacturing;

FIG. 22 is a schematic cross-sectional view for describing a method of manufacturing a semiconductor device according to a comparative example;

FIG. 23 is a schematic cross-sectional view illustrating a part of a configuration of a modification 1 of the semiconductor device according to the first embodiment;

FIG. 24 is a schematic cross-sectional view illustrating a part of a configuration of a modification 2 of the semiconductor device according to the first embodiment;

FIG. 25 is a schematic cross-sectional view illustrating a part of a configuration of a semiconductor device according to the second embodiment;

FIG. 26 is a schematic plan view illustrating a part of the configuration of the semiconductor device;

FIG. 27 is a schematic cross-sectional view for describing a method of manufacturing the semiconductor device;

FIG. 28 is a schematic cross-sectional view for describing the method of manufacturing;

FIG. 29 is a schematic cross-sectional view for describing the method of manufacturing;

FIG. 30 is a schematic cross-sectional view illustrating a part of a configuration of a semiconductor device according to a third embodiment;

FIG. 31 is a schematic cross-sectional view for describing a method of manufacturing the semiconductor device;

FIG. 32A is a schematic cross-sectional view illustrating a part of a configuration of a semiconductor device according to a fourth embodiment;

FIG. 32B is a schematic cross-sectional view illustrating a part of the configuration of the semiconductor device according to the fourth embodiment;

FIG. 33 is a schematic cross-sectional view for describing a method of manufacturing the semiconductor device;

FIG. 34 is a schematic cross-sectional view for describing the method of manufacturing;

FIG. 35 is a schematic cross-sectional view for describing the method of manufacturing;

FIG. 36 is a schematic cross-sectional view for describing the method of manufacturing;

FIG. 37 is a schematic cross-sectional view illustrating a part of a configuration of a modification 1 of the semiconductor device according to the fourth embodiment;

FIG. 38 is a schematic cross-sectional view for describing a method of manufacturing the modification 1 of the semiconductor device;

FIG. 39 is a schematic cross-sectional view for describing the method of manufacturing;

FIG. 40 is a schematic cross-sectional view illustrating a part of a configuration of a modification 2 of the semiconductor device according to the fourth embodiment;

FIG. 41 is a schematic cross-sectional view illustrating a part of a configuration of a modification 3 of the semiconductor device according to the fourth embodiment;

FIG. 42 is a schematic cross-sectional view for describing a method of manufacturing the modification 3 of the semiconductor device;

FIG. 43 is a schematic cross-sectional view for describing the method of manufacturing;

FIG. 44 is a schematic cross-sectional view for describing the method of manufacturing;

FIG. 45 is a schematic cross-sectional view for describing the method of manufacturing;

FIG. 46 is a schematic cross-sectional view for describing the method of manufacturing;

FIG. 47A is a schematic cross-sectional view illustrating a part of a configuration of a semiconductor device according to a fifth embodiment;

FIG. 47B is a schematic cross-sectional view illustrating a part of the configuration of the semiconductor device according to the fifth embodiment;

FIG. 48 is a schematic cross-sectional view for describing a method of manufacturing the semiconductor device;

FIG. 49 is a schematic cross-sectional view for describing the method of manufacturing;

FIG. 50 is a schematic cross-sectional view for describing the method of manufacturing;

FIG. 51 is a schematic cross-sectional view for describing the method of manufacturing;

FIG. 52 is a schematic cross-sectional view illustrating a part of a configuration of a modification 1 of the semiconductor device according to the fifth embodiment;

FIG. 53 is a schematic cross-sectional view illustrating a part of a configuration of a modification 2 of the semiconductor device according to the fifth embodiment;

FIG. 54 is a schematic cross-sectional view illustrating a part of a configuration of a semiconductor device according to a sixth embodiment;

FIG. 55 is a schematic cross-sectional view for describing a method of manufacturing the semiconductor device;

FIG. 56 is a schematic cross-sectional view for describing the method of manufacturing; and

FIG. 57 is a schematic cross-sectional view illustrating a part of a configuration of a semiconductor device according to another embodiment.

### DETAILED DESCRIPTION

A semiconductor device according to one embodiment comprises a substrate, an oxide semiconductor layer spaced from the substrate in a first direction intersecting with a surface of the substrate, a first wiring opposed to a part of the oxide semiconductor layer, a gate insulating film disposed between the oxide semiconductor layer and the first wiring, a second wiring electrically connected to one end in the first direction of the oxide semiconductor layer, and a first insulating layer disposed on a surface on one side and a surface on the other side in a second direction intersecting with the first direction of the second wiring. The second wiring contains a first metallic element, and the first insulating layer contains the first metallic element and oxygen (O).

Next, the semiconductor devices according to embodiments are described in detail with reference to the drawings. The following embodiments are only examples, and not described for the purpose of limiting the present invention. The following drawings are schematic, and for convenience of description, a part of a configuration and the like is sometimes omitted. Parts common in a plurality of embodiments are attached by same reference numerals and their descriptions may be omitted.

In this specification, when it is referred that a first configuration “is electrically connected” to a second configuration, the first configuration may be directly connected to the second configuration, and the first configuration may be connected to the second configuration via a wiring, a semiconductor member, a transistor, or the like. For example, when three transistors are connected in series, even when the second transistor is in an OFF state, the first transistor is “electrically connected” to the third transistor.

In this specification, a direction parallel to an upper surface of the substrate is referred to as an X-direction, a direction parallel to the upper surface of the substrate and perpendicular to the X-direction is referred to as a Y-direction, and a direction perpendicular to the upper surface of the substrate is referred to as a Z-direction.

In this specification, a direction along a predetermined plane may be referred to as a first direction, a direction along this predetermined plane and intersecting with the first direction may be referred to as a second direction, and a direction intersecting with this predetermined plane may be referred to as a third direction. These first direction, second direction, and third direction may each correspond to any of the X-direction, the Y-direction, and the Z-direction and need not correspond to these directions.

Expressions such as “above” and “below” in this specification are based on the substrate. For example, a direction away from the substrate along the Z-direction is referred to as above and a direction approaching the substrate along the Z-direction is referred to as below. A lower surface and a lower end of a certain configuration mean a surface and an end portion on a substrate side of this configuration. An upper surface and an upper end of a certain configuration mean a surface and an end portion on a side opposite to the substrate of this configuration. A surface intersecting with the X-direction or the Y-direction is referred to as a side surface and the like.

### First Embodiment

### Circuit Configuration

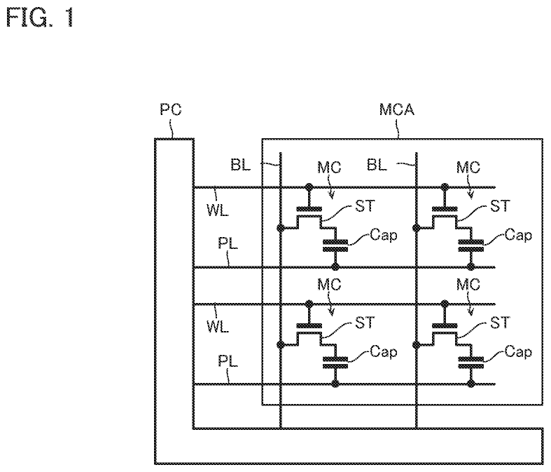

A semiconductor device according to the first embodiment includes, for example, a memory cell array MCA and a peripheral circuit PC as illustrated in FIG. 1.

The memory cell array MCA includes a plurality of bit lines BL, a plurality of word lines WL, a plurality of plate lines PL, and a plurality of memory cells MC that are connected to the plurality of bit lines BL, the plurality of word lines WL, and the plurality of plate lines PL. A plurality of memory cells MC connected to one word line WL are connected to the respective mutually different bit lines BL. A plurality of memory cells MC connected to one bit line BL are connected to the respective mutually different word lines WL.

Each of the memory cells MC includes a select transistor ST and a capacitor Cap that are connected in series between the bit line BL and the plate line PL.

The select transistor ST is a field-effect type transistor including a semiconductor layer that functions as a channel region, a gate insulating film, and a gate electrode. Each gate electrode of the select transistor ST is connected to the word line WL.

The capacitor Cap is a capacitor that includes a pair of electrodes and an insulating film. The capacitor Cap includes a memory portion.

The peripheral circuit PC includes, for example, a voltage generation circuit that generates an operating voltage and outputs the operating voltage to a voltage supply line, a decode circuit that electrically conducts a desired voltage supply line to each of the wirings (the bit lines BL, the word lines WL, and the plate lines PL) in the memory cell array MCA, a sense amplifier circuit that senses a current or a voltage of the bit lines BL, and the like.

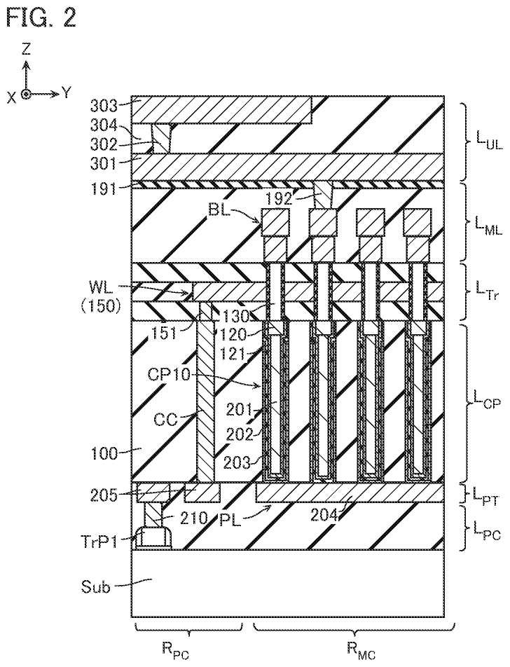

FIG. 2 is a schematic cross-sectional view illustrating a part of a configuration of the semiconductor device. As illustrated in FIG. 2, the semiconductor device according to the first embodiment includes a substrate Sub, a transistor layer L_{Tr} spaced from the substrate Sub in the Z-direction, a wiring layer L_{ML} disposed above the transistor layer L_{Tr}, a wiring layer L_{UL} disposed above the wiring layer L_{ML}, a capacitor layer L_{CP} disposed below the transistor layer L_{Tr}, a plate line layer L_{PT} disposed below the capacitor layer L_{CP}, and a peripheral circuit layer L_{PC} disposed on the substrate Sub below the plate line layer L_{PT}. The substrate Sub contains, for example, P-type silicon (Si) containing P-type impurities, such as boron (B).

As illustrated in FIG. 2, the semiconductor device according to the first embodiment includes a memory region R_{MC} and a peripheral region R_{PC} which are provided on the substrate Sub.

### Structure of Memory Region R_{MC}

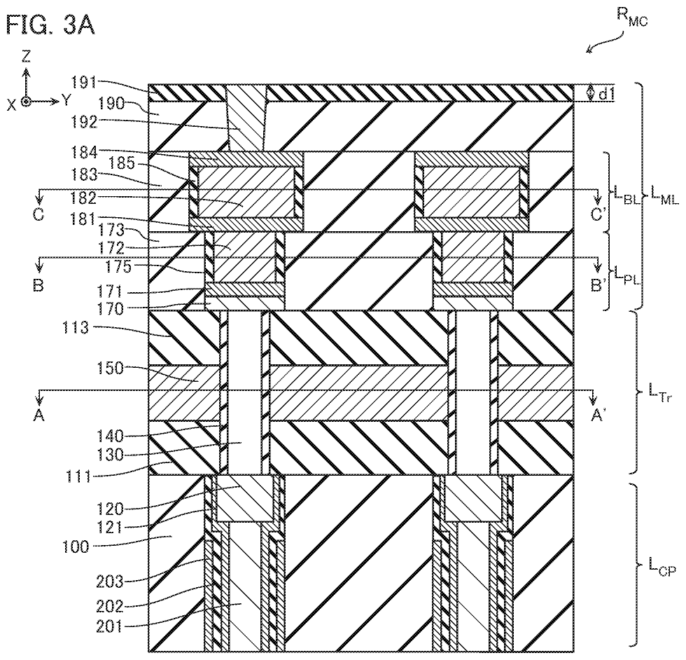

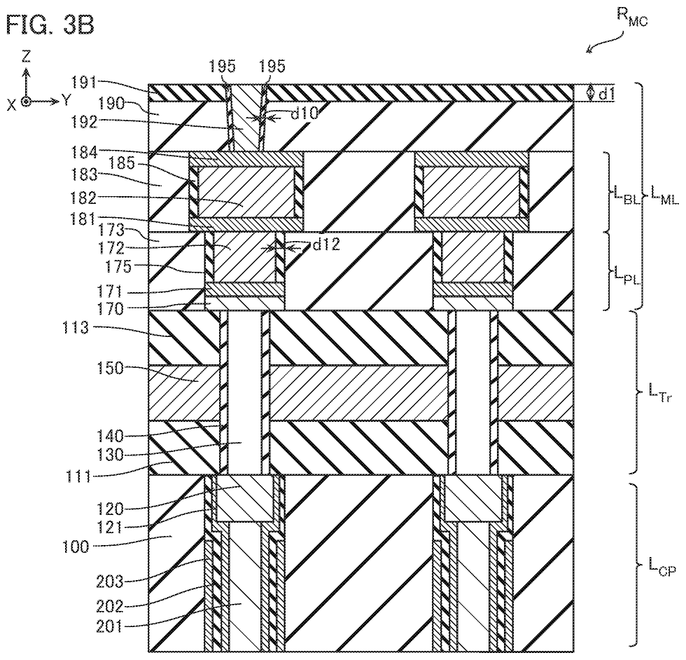

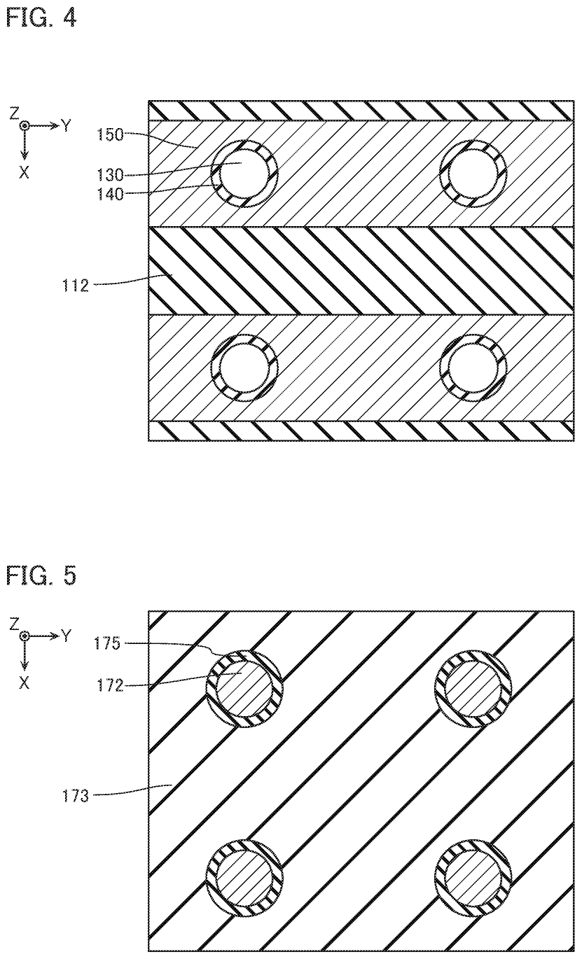

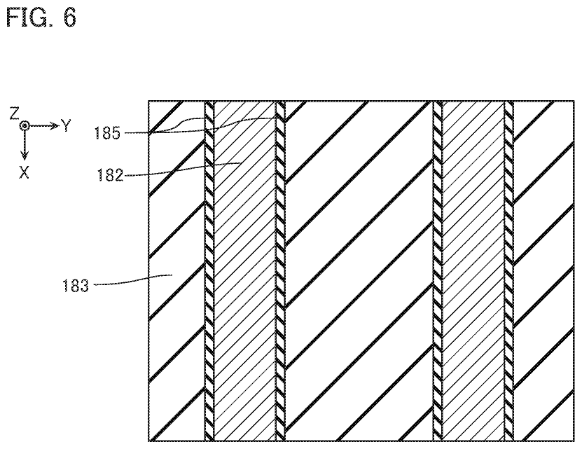

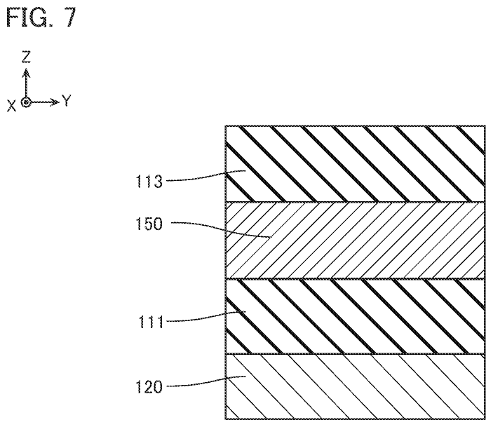

Next, with reference to FIG. 2 to FIG. 6, the structure of the memory region R_{MC} is described. FIG. 3A and FIG. 3B are schematic cross-sectional views illustrating a part of the configuration of the memory region R_{MC}. FIG. 4 is a schematic cross-sectional view of the configuration illustrated in FIG. 3A taken along a line A-A′ viewed in an arrow direction. FIG. 5 is a schematic cross-sectional view of the configuration illustrated in FIG. 3A taken along a line B-B′ viewed in an arrow direction. FIG. 6 is a schematic cross-sectional view of the configuration illustrated in FIG. 3A taken along a line C-C′ viewed in an arrow direction.

The transistor layer L_{Tr} in the memory region R_{MC} includes, for example, as illustrated in FIG. 3A, an insulating layer 111 disposed on an upper surface of the capacitor layer L_{CP} and an insulating layer 113 disposed above the insulating layer 111. The transistor layer L_{Tr} in the memory region R_{MC} includes, for example, as illustrated in FIG. 4, a plurality of insulating layers 112 and a plurality of conductive layers 150 which are disposed between the insulating layer 111 and the insulating layer 113 and alternately arranged in the X-direction. The transistor layer L_{Tr} in the memory region R_{MC} includes, for example, as illustrated in FIG. 4, a plurality of semiconductor layers 130 arranged in the X-direction and the Y-direction corresponding to the plurality of conductive layers 150 and insulating layers 140 disposed on outer peripheral surfaces of the semiconductor layers 130.

The insulating layer 111, the insulating layer 112, and the insulating layer 113 contain, for example, silicon oxide (SiO₂).

The semiconductor layer 130 extends, for example, in the Z-direction, and has an approximately columnar shape. The semiconductor layer 130 is an oxide semiconductor, and functions as, for example, a channel region of the select transistor ST (FIG. 1). For example, the semiconductor layer 130 contains at least one element selected from the group consisting of indium (In), gallium (Ga), zinc (Zn), magnesium (Mg), aluminum (Al), calcium (Ca), titanium (Ti), manganese (Mn), cadmium (Cd), and tin (Sn), and contains zinc (Zn) and oxygen (O). The semiconductor layer 130 contains, for example, indium (In), gallium (Ga), zinc (Zn), and oxygen (O).

The insulating layer 140 extends, for example, in the Z-direction, and has an approximately cylindrical shape. The insulating layer 140 functions as, for example, a gate insulating film of the select transistor ST (FIG. 1). The insulating layer 140 contains, for example, silicon oxide (SiO₂). The insulating layer 140 may be a stacked structure of silicon oxide (SiO₂) and an insulating layer of silicon nitride (SiN) or another high dielectric constant material.

The conductive layer 150 functions as, for example, gate electrodes of a plurality of the select transistors ST arranged in the Y-direction and a word line WL (FIG. 1) of the memory cell array MCA. The conductive layer 150 may contain, for example, tungsten (W) or a stacked structure of titanium nitride (TiN) and tungsten (W).

For example, as illustrated in FIG. 3A, the wiring layer L_{ML} of the memory region R_{MC} includes a plug layer L_{PL} disposed on an upper surface of the transistor layer L_{Tr}, a bit line layer L_{BL} disposed on an upper surface of the plug layer L_{PL}, a conductive layer 192 and an insulating layer 190 of silicon oxide (SiO₂) or the like disposed on an upper surface of the bit line layer L_{BL}, and a metal oxide layer 191 disposed on an upper surface of the insulating layer 190.

For example, as illustrated in FIG. 3A and FIG. 5, the plug layer L_{PL} includes a conductive layer 170, a conductive layer 171, and a conductive layer 172 and an insulating layer 175 disposed in the order on the upper surface of the transistor layer L_{Tr} at positions corresponding to the semiconductor layers 130. The conductive layer 170, the conductive layer 171, and the conductive layer 172 are each electrically connected to the semiconductor layer 130. The insulating layer 175 is disposed at a surface on a Y-direction positive side and a surface on a Y-direction negative side of the conductive layer 172 in, for example, a YZ cross-sectional surface illustrated in FIG. 3A. The insulating layer 175 is disposed on an outer peripheral surfaces of the conductive layers 172 in, for example, an XY cross-sectional surface illustrated in FIG. 5.

The structure including the conductive layer 170, the conductive layer 171, the conductive layer 172, and the insulating layer 175 has, for example, as illustrated in FIG. 3A and FIG. 5, an approximately columnar shape extending in the Z-direction, and a plurality of the structures are disposed to be arranged in the X-direction and the Y-direction. The conductive layer 170, the conductive layer 171, and the conductive layer 172 function as, for example, a source electrode of the select transistor ST. Between the plurality of structures including these conductive layer 170, conductive layer 171, conductive layer 172, and insulating layer 175, for example, an insulating layer 173 of silicon oxide (SiO₂) or the like is disposed.

The conductive layer 170 contains, for example, at least one element selected from the group consisting of indium (In), tin (Sn), niobium (Nb), titanium (Ti), tungsten (W), ruthenium (Ru), tantalum (Ta), iridium (Ir), and molybdenum (Mo), and contains oxygen (O). The conductive layer 170 may be, for example, indium tin oxide (InSnO).

The conductive layer 171 contains, for example, titanium nitride (TiN).

The conductive layer 172 contains, for example, a metallic element ME1. The metallic element ME1 is, for example, a metallic element, such as tungsten (W), aluminum (Al), and molybdenum (Mo).

The insulating layer 175 contains, for example, the metallic element ME1 and oxygen (O). The insulating layer 175 may be a metal oxide, such as tungsten oxide (WO), aluminum oxide (AlO), and molybdenum oxide (MoO).

For example, as illustrated in FIG. 3A and FIG. 6, the bit line layer L_{BL} includes a conductive layer 181, a conductive layer 182 and an insulating layer 185, and a conductive layer 184 disposed in the order on the upper surface of the plug layer L_{PL} at positions corresponding to the conductive layers 172.

Each of the conductive layer 181, the conductive layer 182, and the conductive layer 184 is electrically connected to a plurality of the conductive layers 172 arranged in the X-direction. For example, as illustrated in FIG. 5 and FIG. 6, the insulating layer 185 is disposed on a surface on the Y-direction positive side and a surface on the Y-direction negative side of the conductive layer 182.

The structure including the conductive layer 181, the conductive layer 182 and the insulating layer 185, and the conductive layer 184 extends, for example, as illustrated in FIG. 3A and FIG. 6, in the X-direction, and a plurality of the structures are disposed to be arranged in the Y-direction. The conductive layer 181, the conductive layer 182, and the conductive layer 184 function as, for example, bit lines BL (FIG. 1) of the memory cell array MCA. Between these structures arranged in the Y-direction, for example, an insulating layer 183 of silicon oxide (SiO₂) or the like is disposed.

The conductive layer 181 and the conductive layer 184 contain, for example, titanium nitride (TiN).

The conductive layer 182 contains, for example, a metallic element ME2. The metallic element ME2 is, for example, a metallic element, such as tungsten (W), aluminum (Al), and molybdenum (Mo).

The insulating layer 185 contains, for example, the metallic element ME2 and oxygen (O). The insulating layer 185 may be a metal oxide, such as tungsten oxide (WO), aluminum oxide (AlO), and molybdenum oxide (MoO).

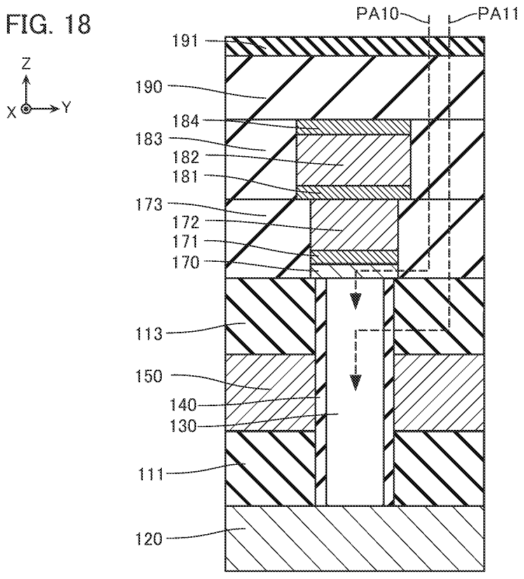

The metal oxide layer 191 functions as, for example, a layer to enhance an oxygen introduction efficiency to the semiconductor layer 130 in a first oxidation process (FIG. 18) described later. Further, the metal oxide layer 191 functions as a layer to avoid reduction of the semiconductor layer 130 (occurrence of deoxygenation (O)) due to a reducing gas, such as hydrogen (H), used in a process of forming the wiring layer L_{UL} (FIG. 2) described later.

The metal oxide layer 191 contains a metallic element ME3 and oxygen (O). The metallic element ME3 is, for example, at least one metallic element selected from the group consisting of aluminum (Al), hafnium (Hf), zirconium (Zr), lanthanum (La), yttrium (Y), titanium (Ti), nickel (Ni), zinc (Zn), indium (In), tin (Sn), gallium (Ga), and tungsten (W).

The metal oxide layer 191 contains, for example, the metallic element ME3 and oxygen (O) as main components. The metal oxide layer 191 may contain, for example, a metal oxide, such as aluminum oxide (AlO), hafnium oxide (HfO), zirconium oxide (ZrO), lanthanum oxide (LaO), yttrium oxide (YO), titanium oxide (TiO), nickel oxide (NiO), zinc oxide (ZnO), indium oxide (InO), tin oxide (Sno), gallium oxide (GaO), or tungsten oxide (WO). When the metal oxide layer 191 contains aluminum oxide (AlO), hafnium oxide (HfO), zirconium oxide (ZrO), lanthanum oxide (LaO), or yttrium oxide (YO), the insulating property of the metal oxide layer improves.

The metal oxide layer 191 may include, for example, an insulating film or a film having a semiconductor property. The metal oxide layer 191 may include, for example, an amorphous film. The metal oxide layer 191 may contain at least one element selected from the group consisting of, for example, nitrogen (N), carbon (C), hydrogen (H), fluorine (F), and chlorine (Cl).

The metal oxide layer 191 has a width d1 (FIG. 3A) in the Z-direction. The width d1 is, for example, 1 nm or more and 5 nm or less.

For example, as illustrated in FIG. 2 and FIG. 3A, the conductive layer 192 extends in the Z-direction, and has an approximately columnar shape. The conductive layer 192 has a lower surface connected to the conductive layer 184. The conductive layer 192 has an upper surface provided at a position, for example, same as an upper surface of the metal oxide layer 191. The conductive layer 192 is disposed, for example, to penetrate the metal oxide layer 191. The conductive layer 192 may contain, for example, tungsten (W) or a stacked structure of titanium nitride (TiN) and tungsten (W).

For example, as illustrated in FIG. 3B, the conductive layer 192 may include an insulating layer 195 on an outer peripheral surface of the conductive layer 192. The insulating layer 195 contains, for example, a metallic element contained in the conductive layer 192 and oxygen (O). The insulating layer 195 may be, for example, a metal oxide, such as tungsten oxide (WO).

The insulating layer 195 has a width d10 in a thickness direction. The width d10 is smaller than a width d12 of the insulating layer 175 in its thickness direction.

For example, as illustrated in FIG. 2, the wiring layer L_{UL} includes a wiring 301 disposed on the upper surface of the metal oxide layer 191, a wiring 302 disposed on an upper surface of the wiring 301 to be connected to the wiring 301, and a wiring 303 disposed on an upper surface of the wiring 302 to be connected to the wiring 302. Between the wiring 301, the wiring 302, and the wiring 303, for example, an insulating layer 304 of silicon oxide (SiO₂) or the like is disposed.

The wiring 301, the wiring 302, and the wiring 303 function as, for example, wirings for applying a voltage and a current to the bit line BL. The wiring 301, the wiring 302, and the wiring 303 contain, for example, copper (Cu), tungsten (W), and aluminum (Al).

For example, as illustrated in FIG. 2 and FIG. 3A, the capacitor layer L_{CP} in the memory region R_{MC} includes a plurality of conductive layers 120 disposed corresponding to the plurality of semiconductor layers 130 and connected to respective lower ends of the plurality of semiconductor layers 130, a plurality of conductive layers 201 disposed corresponding to these plurality of conductive layers 120 and connected to respective lower ends of the plurality of conductive layers 120, and a plurality of conductive layers 121 disposed on outer peripheral surfaces of these plurality of conductive layers 120 and outer peripheral surfaces and lower surfaces of the plurality of conductive layers 201. The capacitor layer L_{CP} includes insulating layers 202 disposed on outer peripheral surfaces and lower surfaces of the conductive layers 121 and conductive layers 203 disposed on outer peripheral surfaces and lower surfaces of the insulating layers 202 (FIG. 3A). In the following description, these configurations that achieve the capacitor Cap (FIG. 1) disposed in the capacitor layer L_{CP} of the memory region R_{MC} are referred to as a “capacitor structure CP10” in some cases. The capacitor structure CP10 includes, for example the conductive layer 120, the conductive layer 121, the conductive layer 201, the insulating layer 202, and the conductive layer 203. Between a plurality of the capacitor structures CP10, for example, an insulating layer 100 of silicon oxide (SiO₂) or the like is disposed.

The conductive layer 120 functions as, for example, a drain electrode of the select transistor ST (FIG. 1) and a part of one electrode of the capacitor Cap (FIG. 1). The conductive layer 120 has an approximately circular shape in the XY cross-sectional surface, and may have a plug shape. The conductive layer 120 contains, for example, a material similar to that of the conductive layer 170. The conductive layer 120 may be, for example, indium tin oxide (InSnO).

The conductive layer 121 functions as, for example, a part of the one electrode of the capacitor Cap (FIG. 1). The conductive layer 121 may be, for example, titanium nitride (TiN).

The conductive layer 201 functions as a part of the one electrode of the capacitor Cap (FIG. 1). The conductive layer 201 includes, for example, a stacked structure of titanium nitride (TiN) and tungsten (W).

The insulating layer 202 functions as an insulating layer between the electrodes of the capacitor Cap (FIG. 1). The insulating layer 202 contains, for example, aluminum oxide (AlO). The insulating layer 202 may be, for example, silicon oxide (SiO₂) or another insulating metal oxide.

The conductive layer 203 functions as, for example, the other electrode of the capacitor Cap (FIG. 1). The conductive layer 203 includes, for example, a stacked structure of titanium nitride (TiN) and tungsten (W).

For example, as illustrated in FIG. 2, the plate line layer L_{PT} in the memory region R_{MC} includes a conductive layer 204 disposed at a lower surface of the capacitor layer L_{CP}. The conductive layer 204 is electrically connected to a plurality of the conductive layers 203. The conductive layer 204 functions as, for example, a plate line PL (FIG. 1). The conductive layer 204 may contain, for example, tungsten (W) or a stacked structure of titanium nitride (TiN) and tungsten (W).

### Structure of Peripheral Region R_{PC}

For example, as illustrated in FIG. 2, the transistor layer L_{Tr} in the peripheral region R_{PC} includes a part of the conductive layer 150 that functions as a word line WL and an electrode 151 connected to a lower end of the conductive layer 150. The electrode 151 may contain, for example, tungsten (W) or a stacked structure of titanium nitride (TiN) and tungsten (W).

For example, as illustrated in FIG. 2, the capacitor layer L_{CP} in the peripheral region R_{PC} includes a plurality of electrodes CC extending in the Z-direction. For example, the electrode CC has an upper end electrically connected to the electrode 151 and a lower end electrically connected to a part of a plurality of conductive layers 205 (described later) in the plate line layer L_{PT}. The electrode CC may contain, for example, tungsten (W) or a stacked structure of titanium nitride (TiN) and tungsten (W).

For example, as illustrated in FIG. 2, the plate line layer L_{PT} in the peripheral region R_{PC} includes a plurality of conductive layers 205. The conductive layer 205 may contain, for example, a material similar to that of the conductive layer 204.

For example, as illustrated in FIG. 2, the peripheral circuit layer L_{PC} of the peripheral region R_{PC} includes a plurality of transistors TrP1 disposed on the substrate Sub and a plurality of electrodes 210 connected to the plurality of transistors TrP1. The plurality of electrodes 210 have upper ends connected to the conductive layers 205. The respective plurality of electrodes 210 are connected to source regions, drain regions, gate electrodes, and the like of the plurality of transistors TrP1. The plurality of transistors TrP1 constitute, for example, the peripheral circuit PC (FIG. 1).

### Manufacturing Method of First Embodiment

Next, with reference to FIG. 7 to FIG. 21, a method of manufacturing the semiconductor device according to the embodiment is described. FIG. 7 to FIG. 21 are schematic cross-sectional views for describing the method of manufacturing the semiconductor device according to the first embodiment. Hereinafter, the drawings according to the manufacturing method are schematically illustrated, and for convenience of description, a part of a configuration and the like is omitted in some cases.

In the manufacturing method, the peripheral circuit layer L_{PC} (FIG. 2), the plate line layer L_{PT} (FIG. 2), and the capacitor layer L_{CP} (FIG. 2) are formed above the substrate Sub (not illustrated). For example, as illustrated in FIG. 7, on the upper surface of the capacitor layer L_{CP} including the conductive layer 120, the insulating layer 111, the insulating layer 112 (FIG. 4) and the conductive layer 150, and the insulating layer 113 are formed in the order. This process is performed by, for example, Chemical Vapor Deposition (CVD) and Reactive Ion Etching (RIE).

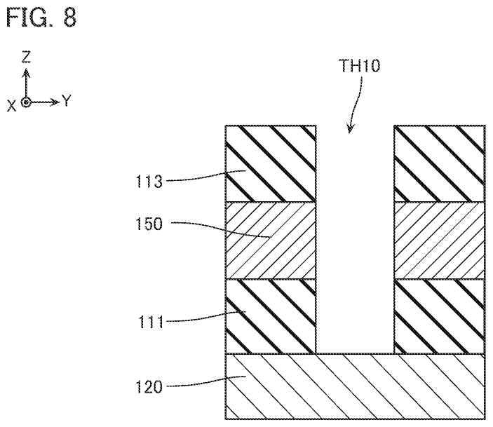

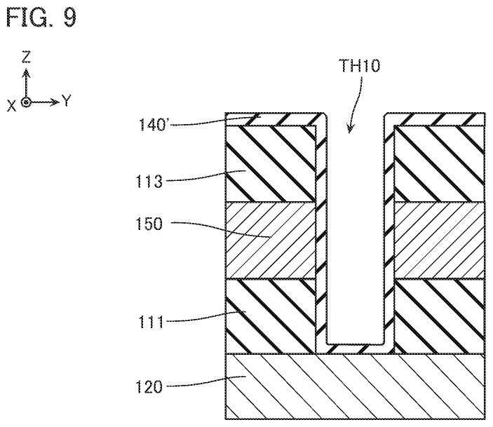

Next, for example, as illustrated in FIG. 8, an opening TH10 is formed. The opening TH10 extends in the Z-direction, penetrates the insulating layer 113, the conductive layer 150, and the insulating layer 111, and exposes the conductive layer 120. This process is performed by, for example, RIE.

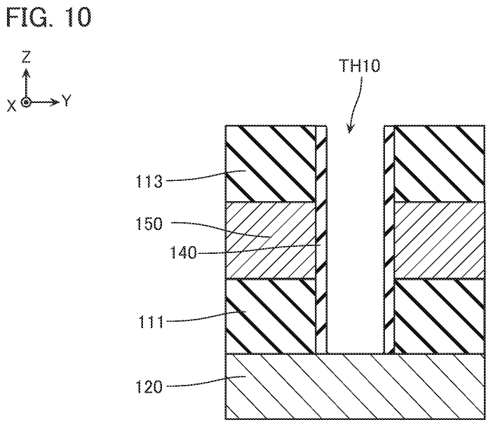

Next, for example, as illustrated in FIG. 9, an insulating layer 140′ is formed on an upper surface of the insulating layer 113 and an inner side surface and a bottom surface of the opening TH10. The insulating layer 140′ contains, for example, a material similar to that of the insulating layer 140. This process is performed by for example, Atomic Layer Deposition (ALD) or CVD.

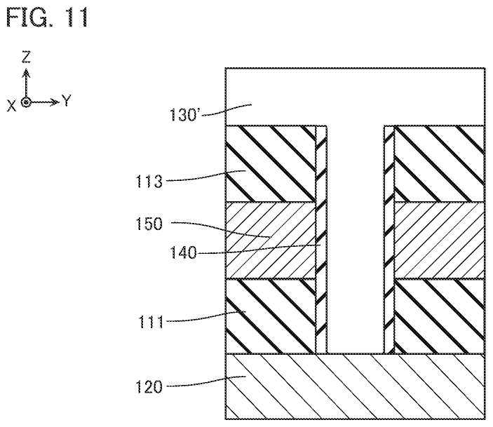

Next, for example, as illustrated in FIG. 10, a part formed on the upper surface of the insulating layer 113 and the bottom surface of the opening TH10 in the insulating layer 140′ is removed to form the insulating layer 140 on the inner side surface of the opening TH10. This process exposes the conductive layer 120 to the bottom surface of the opening TH10. This process is performed by, for example, RIE.

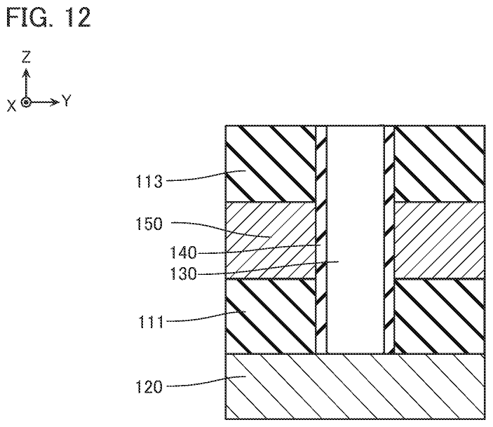

Next, for example, as illustrated in FIG. 11, a semiconductor layer 130′ is formed inside the opening TH10 and on the upper surface of the insulating layer 113. The semiconductor layer 130′ contains, for example, a material similar to that of the semiconductor layer 130. This process is performed by, for example, CVD or ALD.

Next, for example, as illustrated in FIG. 12, a part of the semiconductor layer 130′ formed outside the part provided with the opening TH10 is removed and planarized to form the semiconductor layer 130. This process is performed by, for example, Chemical Mechanical Planarization (CMP) or RIE.

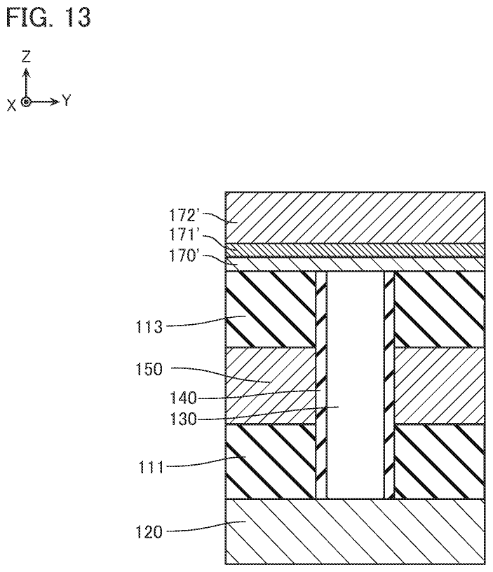

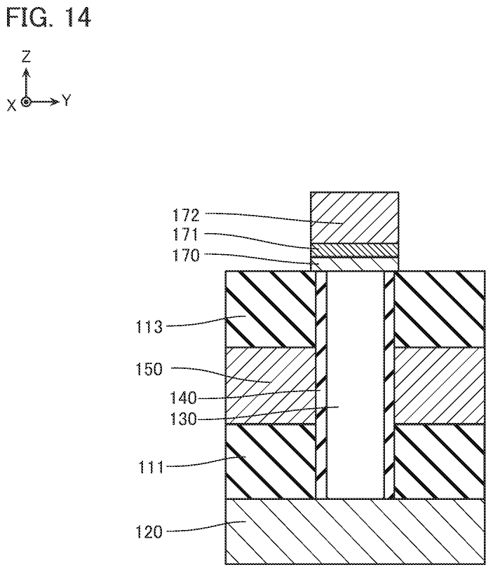

Next, for example, as illustrated in FIG. 13, on an upper surface of the structure illustrated in FIG. 12, a conductive layer 170′, a conductive layer 171′, and a conductive layer 172′ are formed in the order. The conductive layer 170′, the conductive layer 171′, and the conductive layer 172′ contain, for example, materials similar to those of the conductive layer 170, the conductive layer 171, and the conductive layer 172, respectively. This process is performed by, for example, CVD.

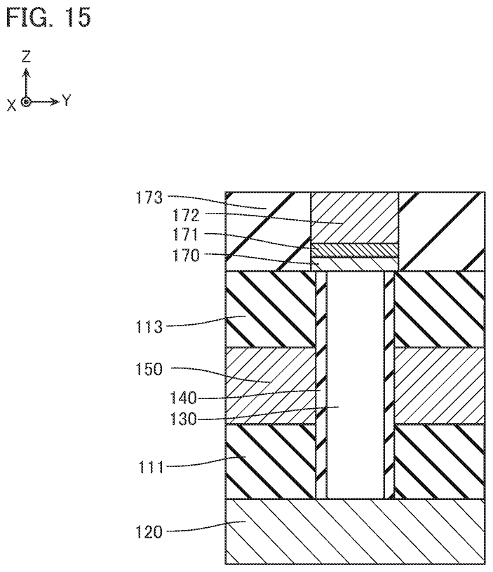

Next, for example, as illustrated in FIG. 14, a mask material is formed at a position corresponding to the conductive layer 170, the conductive layer 171, and the conductive layer 172 by photolithography or the like, and a part not coated with the mask material is removed to form the conductive layer 170, the conductive layer 171, and the conductive layer 172. This process is performed by, for example, RIE.

Next, for example, as illustrated in FIG. 15, a film of a material similar to that of the insulating layer 173 is formed on the upper surface of the insulating layer 113 and an upper surface of the conductive layer 172, and an upper surface of the film is removed and planarized to form the insulating layer 173. This process is performed by, for example, CVD and CMP.

Note that in FIG. 13 to FIG. 15, the process of forming the conductive layer 170, the conductive layer 171, the conductive layer 172, and the insulating layer 173 may be performed by a damascene method. In the damascene method of this process, the insulating layer 173 is formed at first, an opening is formed at a part at which the conductive layer 170, the conductive layer 171, and the conductive layer 172 are to be formed in the insulating layer 173, and the conductive layer 170, the conductive layer 171, and the conductive layer 172 are formed inside the opening. This process is performed by, for example, CVD, RIE, and CMP.

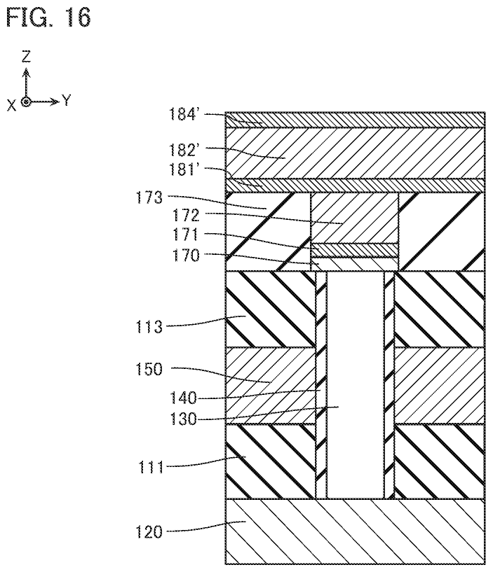

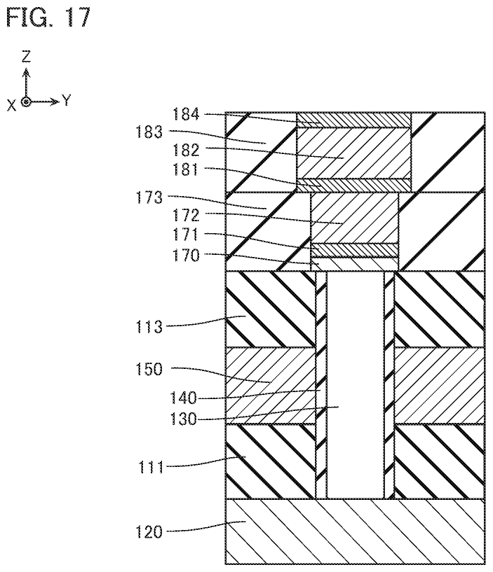

Next, for example, as illustrated in FIG. 16, a conductive layer 181′, a conductive layer 182′, and a conductive layer 184′ are formed on an upper surface of the structure illustrated in FIG. 15 in the order. The conductive layer 181′, the conductive layer 182′, and the conductive layer 184′ contain, for example, materials similar to those of the conductive layer 181, the conductive layer 182, and the conductive layer 184, respectively. This process is performed by, for example, CVD.

Next, for example, as illustrated in FIG. 17, at a position corresponding to the conductive layer 172, the conductive layer 181, the conductive layer 182, and the conductive layer 184 are formed similarly to the process illustrated in FIG. 14. Further, similarly to the process illustrated in FIG. 15, the insulating layer 183 is formed on an upper surface of the insulating layer 173. This process is performed by, for example, RIE, CVD, and CMP.

Note that in FIG. 16 and FIG. 17, the process of forming the conductive layer 181, the conductive layer 182, the conductive layer 184, and the insulating layer 183 may be performed by a damascene method. In the damascene method of this process, the insulating layer 183 is formed at first, an opening is formed at a part at which the conductive layer 181, the conductive layer 182, and the conductive layer 184 are to be formed in the insulating layer 183, and the conductive layer 181, the conductive layer 182, and the conductive layer 184 are formed inside the opening. This process is performed by, for example, CVD, RIE, and CMP.

Next, for example, as illustrated in FIG. 18, the insulating layer 190 and the metal oxide layer 191 are formed on upper surfaces of the insulating layer 183 and the conductive layer 184 in the order. This process is performed by, for example, CVD or ALD.

Further, for example, as illustrated in FIG. 18, a first oxidation process described later is performed in a state where the metal oxide layer 191 is exposed, thereby introducing oxygen to the semiconductor layer 130 through, for example, oxygen introduction paths PA10, PA11.

The oxygen introduction path PA10 is a path that is able to introduce oxygen (O) from the upper surface of the semiconductor layer 130 via the metal oxide layer 191, via the insulating layer 190, the insulating layer 183, and the insulating layer 173 of silicon oxide (SiO₂) or the like, and via the conductive layer 170 of indium tin oxide (InSnO) or the like.

The oxygen introduction path PA11 is a path that is able to introduce oxygen (O) from a side surface of the semiconductor layer 130 via the metal oxide layer 191, and via the insulating layer 190, the insulating layer 183, the insulating layer 173, the insulating layer 113, and the insulating layer 140 of silicon oxide (SiO₂) or the like.

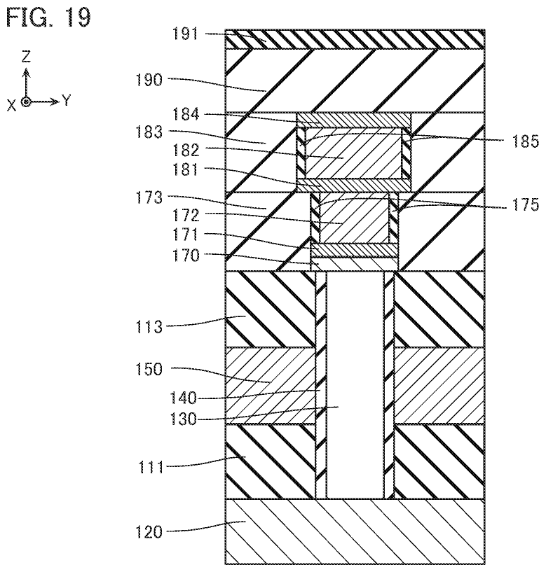

Next, for example, as illustrated in FIG. 19, the first oxidation process is performed to oxidize the outer peripheral surface of the conductive layer 172 and both side surfaces of the conductive layer 182, thereby forming the insulating layer 175 and the insulating layer 185.

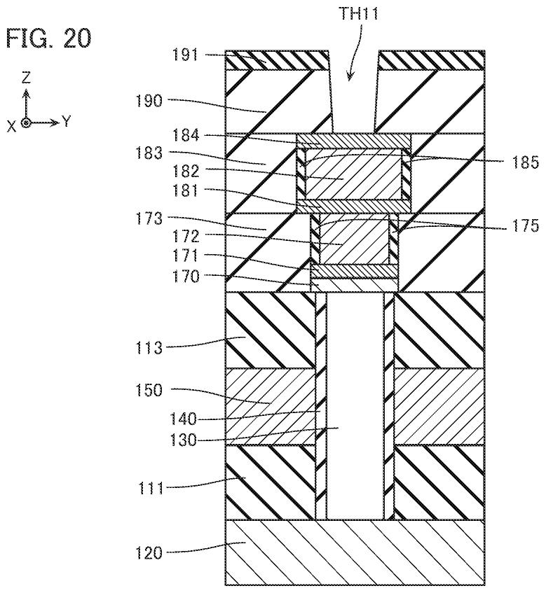

Next, for example, as illustrated in FIG. 20, an opening TH11 is formed. The opening TH11 extends in the Z-direction, penetrates the metal oxide layer 191 and the insulating layer 190, and exposes the conductive layer 184. This process is performed by, for example, RIE.

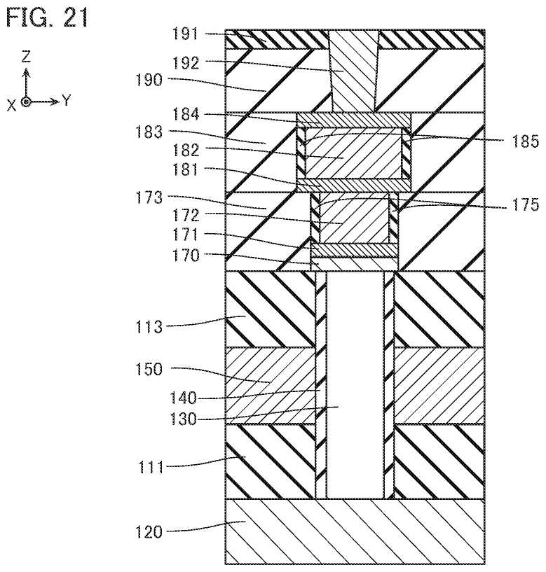

Next, for example, as illustrated in FIG. 21, a film of a material similar to that of the conductive layer 192 is formed inside the opening TH11 and on the upper surface of the metal oxide layer 191, and an upper surface of the film is removed and planarized to form the conductive layer 192. This process is performed by, for example, CVD and CMP.

Next, the wiring layer L_{UL} (FIG. 2) is formed on an upper surface of the structure illustrated in FIG. 21, thus manufacturing the semiconductor device according to the first embodiment. In the process of forming the wiring layer L_{UL} (FIG. 2), a reducing gas, such as hydrogen (H), is used in some cases.

Note that the metal oxide layer 191 (FIG. 21) may be removed before forming the wiring layer L_{UL} (FIG. 2). The metal oxide layer 191 is removed by, for example, RIE, wet etching, or dry etching. By removing the metal oxide layer 191, a dielectric constant between the wirings can be reduced.

In these processes, the insulating layer 195 (FIG. 3B) may be formed on the outer peripheral surface of the conductive layer 192. For example, the conductive layer 192 is in contact with the insulating layer 190 containing oxygen, such as silicon oxide (SiO₂), thereby forming the insulating layer 195.

### First Oxidation Process

The first oxidation process (FIG. 18) is, for example, radical oxidation.

The radical oxidation is performed in an atmosphere containing Oxygen radical or Hydroxyl radical. The radical oxidation is performed in an atmosphere, for example, in which an oxygen gas (O₂), a hydrogen gas (H₂), and an argon gas (Ar) are turned into plasma. The radical oxidation is performed in an atmosphere, for example, in which water vapor is turned into plasma.

A method of generating the oxygen radical and the hydroxyl radical used for the radical oxidation is not specifically limited. The oxygen radical and the hydroxyl radical are generated, for example, using an inductively coupled plasma method, a microwave plasma method, an electron cyclotron resonance method, a helicon wave method, or a hot filament method.

The atmosphere of the radical oxidation contains, for example, hydrogen (H) and oxygen (O). An atomic ratio (H/(H+O)) of the hydrogen (H) to a sum of the hydrogen (H) and the oxygen (O) contained in the atmosphere of the radical oxidation is, for example, 40% or less. The atomic ratio (H/(H+O)) of the hydrogen (H) to the sum of the hydrogen (H) and the oxygen (O) contained in the atmosphere of the radical oxidation is, for example, 2% or more and 5% or less.

The atomic ratio (H/(H+O)) of the hydrogen (H) to the sum of the hydrogen (H) and the oxygen (O) contained in the atmosphere of the radical oxidation is adjusted, for example, using flow rates of a hydrogen gas (H₂) and an oxygen gas (O₂) introduced in the atmosphere of the radical oxidation. A mole ratio (H₂/(H₂+O₂)) of the hydrogen gas (H₂) to a sum of the hydrogen gas (H₂) and the oxygen gas (O₂) introduced in the atmosphere of the radical oxidation is, for example, 40% or less. The mole ratio (H₂/(H₂+O₂)) of the hydrogen gas (H₂) to the sum of the hydrogen gas (H₂) and the oxygen gas (O₂) introduced in the atmosphere of the radical oxidation is, for example, 2% or more and 5% or less.

A temperature of the radical oxidation is, for example, 300° C. or more and 900° C. or less. A pressure of the radical oxidation is, for example, 50 Pa or more and 3000 Pa or less.

When the first oxidation process (FIG. 18) is performed by the radical oxidation, the metal oxide layer 191 preferably contains at least one element selected from the group consisting of nitrogen (N), carbon (C), hydrogen (H), and chlorine (Cl). When the metal oxide layer 191 contains the above-described element, crystallization of the metal oxide layer 191 is reduced, and a degree of oxygen introduction speed increases.

When the first oxidation process (FIG. 18) is performed by the radical oxidation, the atmosphere of the radical oxidation contains hydrogen (H) and oxygen (O), the atomic ratio (H/(H+O)) of the contained hydrogen (H) to the sum of the hydrogen (H) and the oxygen (O) is preferably 40% or less, and more preferably 2% or more and 5% or less. When the atomic ratio (H/(H+O)) meets the above-described range, the degree of the oxygen introduction speed increases.

While the case where, for example, the radical oxidation is performed as the first oxidation process is described above, the method of the first oxidation process can be adjusted as necessary.

For example, as the first oxidation process (FIG. 18), plasma CVD or the like may be used to form a film containing oxygen (O) on the upper surface of the metal oxide layer 191. The plasma CVD is a film forming method performed in, for example, an atmosphere in which an oxygen gas, a hydrogen gas, an argon gas, and the like are turned into plasma. The film containing oxygen (O) is, for example, silicon oxide (SiO₂) or the like.

Further, for example, as the first oxidation process (FIG. 18), oxygen plasma ashing may be performed. The oxygen plasma ashing is a process in which, for example, oxygen plasma in a high energy state is irradiated on the metal oxide layer 191.

The oxygen introduction paths PA10, PA11, and the like in the first oxidation process (FIG. 18) can be measured, for example, by using isotopic oxygen in the first oxidation process and analyzing its distribution by Secondary Ion Mass Spectrometry (SIMS) or the like.

### Comparative Example

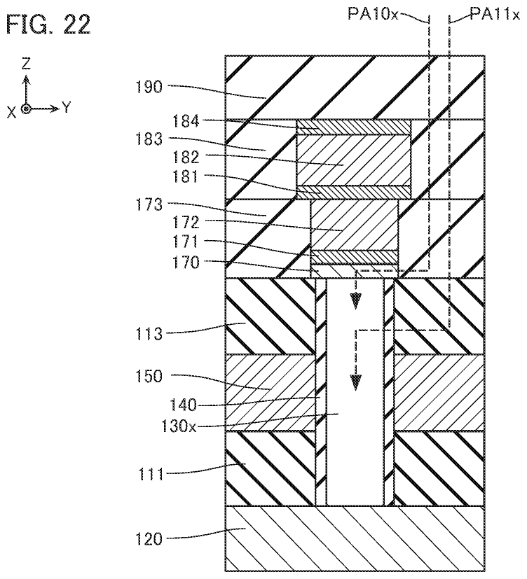

Next, with reference to FIG. 22, a semiconductor device according to a comparative example is described. FIG. 22 is a schematic cross-sectional view for describing a method of manufacturing the semiconductor device according to the comparative example.

In the method of manufacturing the semiconductor device according to the comparative example, in a process (FIG. 22) corresponding to the process illustrated in FIG. 18, the metal oxide layer 191 is not formed, and the above-described first oxidation process is not performed.

In the manufacture of the semiconductor device according to the comparative example, after a semiconductor layer 130x is formed, oxygen atoms in the semiconductor layer 130x become an O₂ gas and are discharged outside the structure in manufacture in some cases. Therefore, an oxygen defect occurs in the semiconductor layer 130x, and the satisfactory switching characteristic of the select transistor ST (FIG. 1) is not provided in some cases.

Further, in the comparative example, since the metal oxide layer 191 (FIG. 2) is not formed, the reducing gas, such as hydrogen (H), used in the process of forming the wiring layer L_{UL} (FIG. 2) in a more upper layer reaches the semiconductor layer 130x via paths PA10x, PA11x in some cases. Therefore, oxygen (O) is detached from the semiconductor layer 130x, thus causing deterioration of the switching characteristic of the select transistor ST (FIG. 1) in some cases.

### Effects

In the semiconductor device according to the embodiment, the oxidation process is performed in the process illustrated in FIG. 18. Accordingly, oxygen is introduced in the semiconductor layer 130.

Here, in the process described with reference to FIG. 18, it is considered to perform an oxidation process as an annealing process in an oxygen (O) atmosphere instead of the above-described first oxidation process.

However, in such an oxidation process, the oxygen introduction efficiency is low compared with the first oxidation process according to the embodiment. Therefore, the sufficient amount of oxygen (O) is not introduced in the semiconductor layer 130x, and the satisfactory switching characteristic of the select transistor ST (FIG. 1) is not provided in some cases.

When the annealing process is performed for a relatively long time at high temperature to introduce the sufficient amount of oxygen (O) in the semiconductor layer 130x, oxidation of the outer peripheral surface of the conductive layer 172 and the side surface of the conductive layer 182 significantly progresses, thereby largely decreasing the widths in the Y-direction of the conductive layer 172 and the conductive layer 182 and significantly increasing a wiring resistance value in some cases.

Therefore, in the semiconductor device according to the embodiment, in the process illustrated in FIG. 18, the first oxidation process that provides the high oxygen introduction efficiency is performed. With this method, the sufficient amount of oxygen is introduced in the semiconductor layer 130, and the progress of oxidation of the outer peripheral surface of the conductive layer 172 and the side surface of the conductive layer 182 is reduced, thus allowing the formation of the insulating layer 175 and the insulating layer 185 having the relatively small widths in the Y-direction as illustrated in FIG. 19. In this case, the widths in the Y-direction of the conductive layer 172 and the conductive layer 182 are not largely decreased, and the wiring resistance value can be made relatively low.

In the semiconductor device according to the embodiment, the metal oxide layer 191 (FIG. 2) is formed before the process of forming the wiring layer LUL (FIG. 2). Here, the metal oxide layer 191 (FIG. 2) is relatively less likely to allow the reducing gas, such as hydrogen (H), to pass through. Therefore, the reducing gas, such as hydrogen (H), used in the process of forming the wiring layer L_{UL} (FIG. 2) does not reach the semiconductor layer 130, and the detachment of oxygen (O) from the semiconductor layer 130 can be avoided. Accordingly, the deterioration of the switching characteristic of the select transistor ST (FIG. 1) in the formation of the wiring layer L_{UL} can be avoided.

Accordingly, with this configuration, the semiconductor device having the excellent transistor characteristic can be provided.

### Modification 1 of First Embodiment

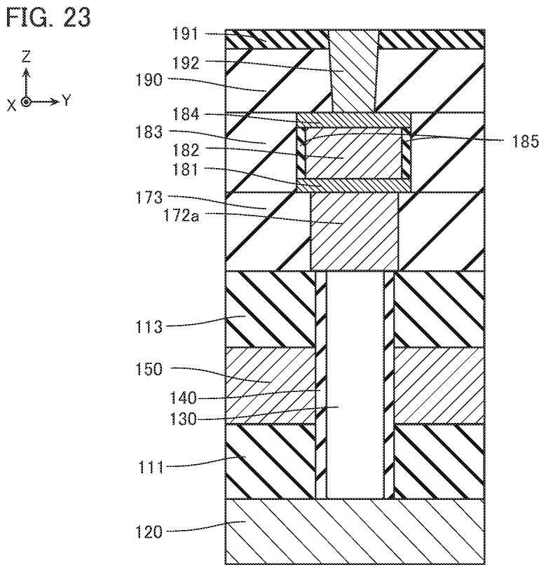

Next, with reference to FIG. 23, the modification 1 of the semiconductor device according to the first embodiment is described. FIG. 23 is a schematic cross-sectional view illustrating a part of a configuration of the semiconductor device according to the modification.

The semiconductor device according to the modification is basically configured similarly to the semiconductor device (FIG. 3A) according to the first embodiment. However, the semiconductor device (FIG. 23) according to the modification includes a conductive layer 172a instead of the conductive layer 170, the conductive layer 171, the conductive layer 172, and the insulating layer 175.

The conductive layer 172a has, for example, an approximately columnar shape extending in the Z-direction, a lower surface connected to the semiconductor layer 130, and an upper surface connected to the conductive layer 181. The conductive layer 172a contains, for example, titanium nitride (TiN), or a noble metal element relatively less likely to be oxidized, such as gold (Au), silver (Ag), copper (Cu), platinum (Pt), and ruthenium (Ru).

In the semiconductor device according to the modification, since the conductive layer 172a contains the material less likely to be oxidized, an insulating layer containing a metal oxide or the like is not formed on an outer peripheral surface of the conductive layer 172a even when the first oxidation process is performed in the process corresponding to the process illustrated in FIG. 18.

### Modification 2 of First Embodiment

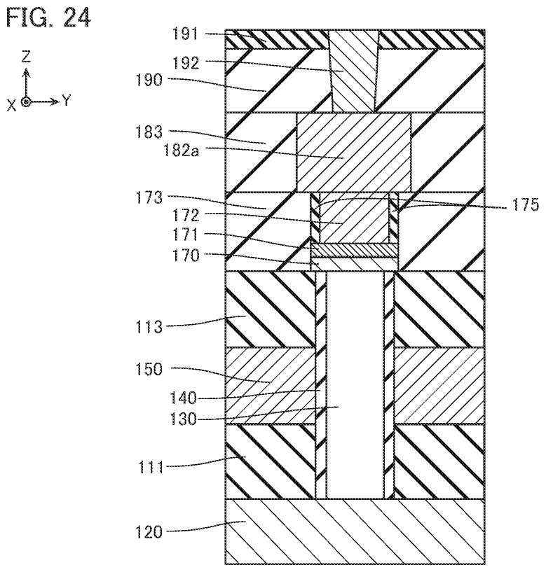

Next, with reference to FIG. 24, the modification 2 of the semiconductor device according to the first embodiment is described. FIG. 24 is a schematic cross-sectional view illustrating a part of a configuration of the semiconductor device according to the modification.

The semiconductor device according to the modification is basically configured similarly to the semiconductor device (FIG. 3A) according to the first embodiment. However, the semiconductor device (FIG. 24) according to the modification includes a conductive layer 182a instead of the conductive layer 181, the conductive layer 182, the conductive layer 184, and the insulating layer 185.

For example, the conductive layer 182a extends in the X-direction, and a plurality of the conductive layers 182a are disposed to be arranged in the Y-direction. The conductive layer 182a contains, for example, a material similar to that of the conductive layer 172a.

In the semiconductor device according to the modification, since the conductive layer 182a contains the material less likely to be oxidized, an insulating layer containing a metal oxide or the like is not formed on both side surfaces of the conductive layer 182a even when the first oxidation process is performed in the process corresponding to the process illustrated in FIG. 18.

### Second Embodiment

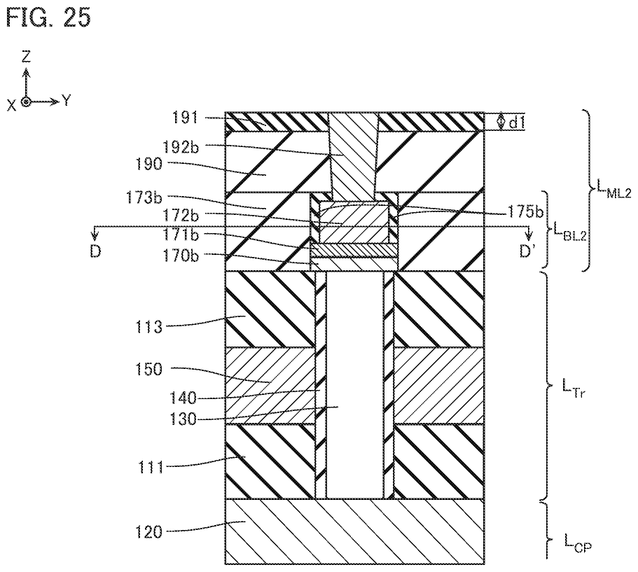

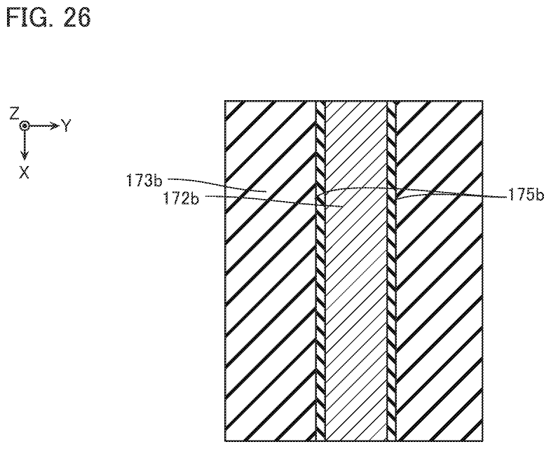

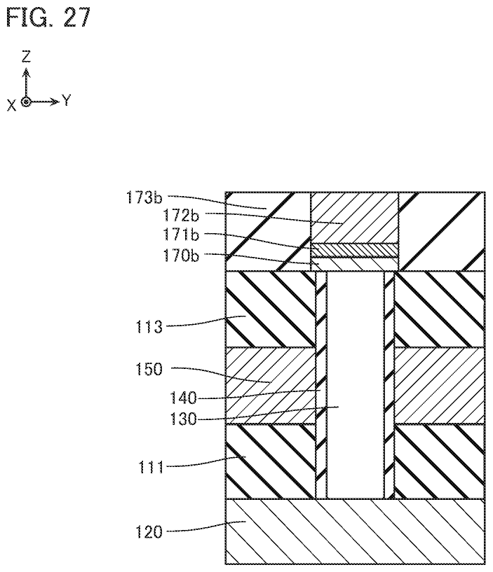

Next, with reference to FIG. 25 and FIG. 26, a semiconductor device according to the second embodiment is described. FIG. 25 is a schematic cross-sectional view illustrating a part of a configuration of the semiconductor device according to the embodiment. FIG. 26 is a schematic plan view of the configuration illustrated in FIG. 25 taken along a line D-D′ viewed in an arrow direction. In the following description, the same reference numerals are attached to configurations similar to those in the first embodiment, and the explanation will be omitted.

The semiconductor device according to the embodiment is basically configured similarly to the semiconductor device (FIG. 3A) according to the first embodiment. However, the semiconductor device (FIG. 25) according to the embodiment includes a wiring layer L_{ML2} instead of the wiring layer L_{ML} (FIG. 3A). The wiring layer L_{ML2} is basically configured similarly to the wiring layer L_{ML}. However, the wiring layer L_{ML2} is not provided with the plug layer L_{PL} (FIG. 3A). The wiring layer L_{ML2} includes a bit line layer L_{BL2} (FIG. 25) instead of the bit line layer L_{BL} (FIG. 3A). The wiring layer L_{ML2} includes a conductive layer 192b instead of the conductive layer 192.

For example, as illustrated in FIG. 25 and FIG. 26, the bit line layer L_{BL2} includes a conductive layer 170b, a conductive layer 171b, and a conductive layer 172b and an insulating layer 175b disposed in the order on the upper surface of the transistor layer L_{Tr} at positions corresponding to the semiconductor layers 130. Each of the conductive layer 170b, the conductive layer 171b, and the conductive layer 172b is electrically connected to a plurality of the semiconductor layers 130 arranged in the X-direction. For example, as illustrated in FIG. 25 and FIG. 26, the insulating layer 175b is disposed at a surface on the Y-direction positive side, a surface on the Y-direction negative side, and a part of a surface on a Z-direction positive side of the conductive layer 172b.

The structure including the conductive layer 170b, the conductive layer 171b, the conductive layer 172b, and the insulating layer 175b extends in the X-direction, for example, as illustrated in FIG. 25 and FIG. 26, and a plurality of the structures are disposed to be arranged in the Y-direction. The conductive layer 170b, the conductive layer 171b, and the conductive layer 172b function as, for example, source electrodes of the plurality of select transistors ST arranged in the X-direction and the bit lines BL (FIG. 1) of the memory cell array MCA. Between these structures arranged in the Y-direction, an insulating layer 173b of silicon oxide (SiO₂) or the like is disposed.

The conductive layer 170b, the conductive layer 171b, the conductive layer 172b, and the insulating layer 175b contain, for example, materials similar to those of the conductive layer 170, the conductive layer 171, the conductive layer 172, and the insulating layer 175 (FIG. 3A), respectively.

The conductive layer 192b contains, for example, a material similar to that of the conductive layer 192 (FIG. 3A). The conductive layer 192b penetrates, for example, the metal oxide layer 191, the insulating layer 190, and the insulating layer 175b, and a lower surface of the conductive layer 192b is connected to the conductive layer 172b.

The conductive layer 192b may include the insulating layer 195 on an outer peripheral surface of the conductive layer 192b similarly to the conductive layer 192, for example, illustrated in FIG. 3B.

### Manufacturing Method of Second Embodiment

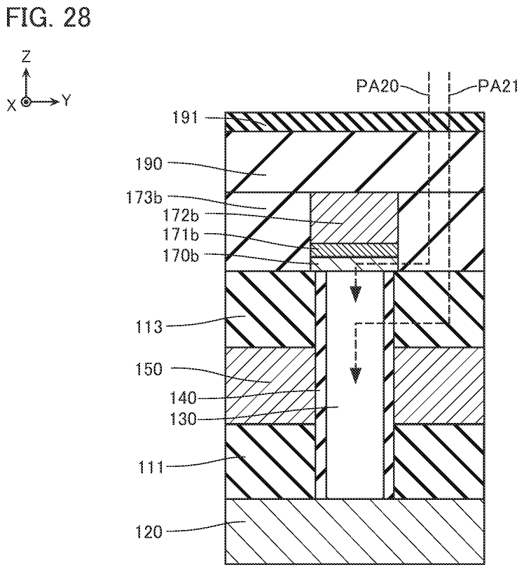

Next, with reference to FIG. 27 to FIG. 29, a method of manufacturing the semiconductor device according to the second embodiment is described. FIG. 27 to FIG. 29 are schematic cross-sectional views for describing the method of manufacturing the semiconductor device according to the second embodiment.

The semiconductor device according to the embodiment is basically manufactured similarly to the semiconductor device according to the first embodiment. However, in the manufacturing method of the semiconductor device according to the embodiment, processes illustrated in FIG. 27 to FIG. 29 are performed next to the processes described with reference to FIG. 7 to FIG. 12.

For example, in the process illustrated in FIG. 27, conductive layers containing materials similar to those of the conductive layer 170b, the conductive layer 171b, and the conductive layer 172b are formed in the order on the upper surface of the structure illustrated in FIG. 12, and subsequently, the conductive layers are removed excluding a part corresponding to the conductive layer 170b, the conductive layer 171b, and the conductive layer 172b, thereby forming the conductive layer 170b, the conductive layer 171b, and the conductive layer 172b. Further, a film of a material similar to that of the insulating layer 173b is formed on the upper surface of the insulating layer 113 and an upper surface of the conductive layer 172b, and subsequently, an upper surface of the film is removed and planarized to form the insulating layer 173b. This process is performed by, for example, CVD or ALD, RIE, and CMP.

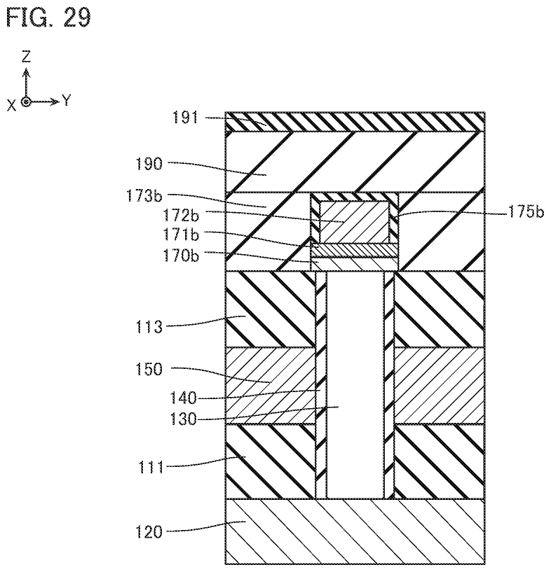

Next, for example, as illustrated in FIG. 28, the insulating layer 190 and the metal oxide layer 191 are formed in the order on the upper surface of the insulating layer 173b and the conductive layer 172b. This process is performed by, for example, CVD or ALD.

Further, for example, as illustrated in FIG. 28, the first oxidation process described above is performed in a state where the metal oxide layer 191 is exposed, thereby introducing oxygen to the semiconductor layer 130 through, for example, oxygen introduction paths PA20, PA21.

The oxygen introduction path PA20 is a path that is able to introduce oxygen (O) from the upper surface of the semiconductor layer 130 via the metal oxide layer 191, via the insulating layer 190 and the insulating layer 173b of silicon oxide (SiO₂) or the like, and via the conductive layer 170b of indium tin oxide (InSnO) or the like.

The oxygen introduction path PA21 is a path that is able to introduce oxygen (O) from the side surface of the semiconductor layer 130 via the metal oxide layer 191, and via the insulating layer 190, the insulating layer 173b, the insulating layer 113, and the insulating layer 140 of silicon oxide (SiO₂) or the like.

Next, for example, as illustrated in FIG. 29, the first oxidation process is performed to oxidize both side surfaces and the upper surface of the conductive layer 172b, thereby forming the insulating layer 175b.

Next, for example, similarly to the process illustrated in FIG. 20, an opening, which extends in the Z-direction and penetrates the metal oxide layer 191, the insulating layer 190, and the insulating layer 175b to expose the conductive layer 172b, is formed, and the conductive layer 192 is formed inside the opening. This process is performed by, for example, RIE, CVD, and CMP.

Next, the wiring layer LUL (FIG. 2) is formed above the metal oxide layer 191 similarly to the first embodiment, thus manufacturing the semiconductor device according to the second embodiment.

Note that the metal oxide layer 191 (FIG. 29) may be removed before forming the wiring layer LUL (FIG. 2). The metal oxide layer 191 is removed by, for example, RIE, wet etching, or dry etching.

### Effects

In the semiconductor device according to the embodiment, since the oxygen introduction paths PA20, PA21 (FIG. 28) from the metal oxide layer 191 to the semiconductor layer 130 are relatively short, the oxygen introduction efficiency in the first oxidation process can be enhanced.

### Third Embodiment

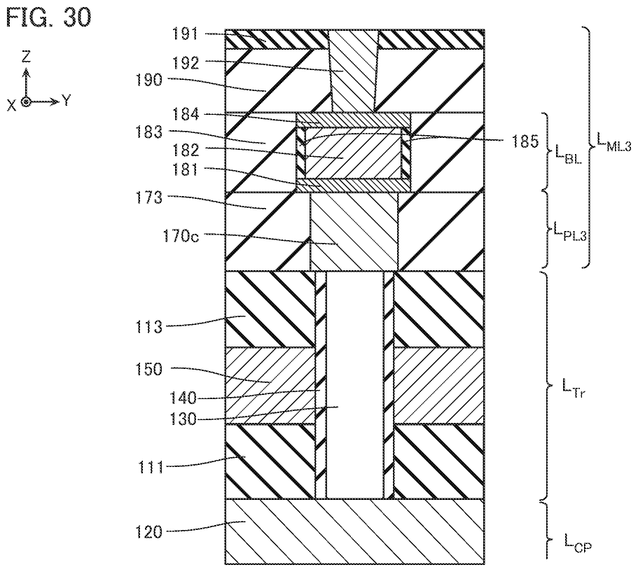

Next, with reference to FIG. 30, a semiconductor device according to third embodiment is described. FIG. 30 is a schematic cross-sectional view illustrating a part of a configuration of the semiconductor device according to the embodiment. In the following description, the same reference numerals are attached to configurations similar to those in the first embodiment, and the explanation will be omitted.

The semiconductor device (FIG. 30) according to the embodiment is basically configured similarly to the semiconductor device (FIG. 3A) according to the first embodiment. However, the semiconductor device according to the embodiment includes a wiring layer L_{ML3} (FIG. 30) instead of the wiring layer L_{ML} (FIG. 3A). The wiring layer L_{ML3} is basically configured similarly to the wiring layer L_{ML}. However, the wiring layer L_{ML3} includes a plug layer L_{PL3} (FIG. 30) instead of the plug layer L_{PL} (FIG. 3A).

The plug layer L_{PL3} is basically configured similarly to the plug layer L_{PL}. However, the plug layer L_{PL3} includes a conductive layer 170c (FIG. 30) instead of the conductive layer 170, the conductive layer 171, the conductive layer 172, and the insulating layer 175 (FIG. 3A).

The conductive layer 170c has an approximately columnar shape extending in the Z-direction, and a plurality of the conductive layers 170c are disposed to be arranged in the X-direction and the Y-direction. The conductive layer 170c functions as, for example, a source electrode of the select transistor ST.

The conductive layer 170c contains, for example, a material similar to that of the conductive layer 170.

### Manufacturing Method of Third Embodiment

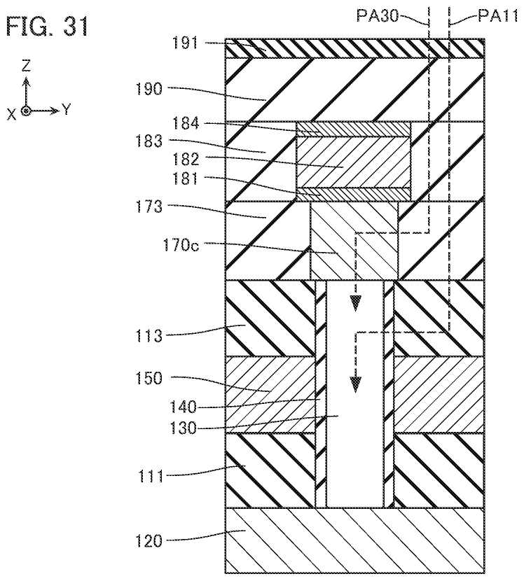

Next, with reference to FIG. 31, a method of manufacturing the semiconductor device according to the third embodiment is described. FIG. 31 is a schematic cross-sectional view for describing the method of manufacturing the semiconductor device according to the third embodiment.

The semiconductor device according to the embodiment is basically manufactured similarly to the semiconductor device according to the first embodiment. However, in the manufacturing method of the semiconductor device according to the embodiment, in a process corresponding to the process described with reference to FIG. 13, a conductive layer containing a material similar to that of the conductive layer 170c is formed instead of the conductive layer 170′, the conductive layer 171′, and the conductive layer 172′. Further, in processes similar to the processes described with reference to FIG. 14 and FIG. 15, the conductive layer 170c and the insulating layer 173 are formed.

Further, for example, as illustrated in FIG. 31, the first oxidation process described above is performed in a state where the metal oxide layer 191 is exposed, thereby introducing oxygen to the semiconductor layer 130 through, for example, oxygen introduction paths PA30, PA11.

The oxygen introduction path PA30 is a path that is able to introduce oxygen (O) from the upper surface of the semiconductor layer 130 via the metal oxide layer 191, via the insulating layer 190, the insulating layer 183, and the insulating layer 173 of silicon oxide (SiO₂) or the like, and via the conductive layer 170c of indium tin oxide (InSnO) or the like.

### Effects

In the semiconductor device according to the embodiment, by forming the conductive layer 170c having a relatively large volume and containing oxygen at the upper surface part of the semiconductor layer 130, the oxygen introduction efficiency in the first oxidation process can be enhanced.

### Fourth Embodiment

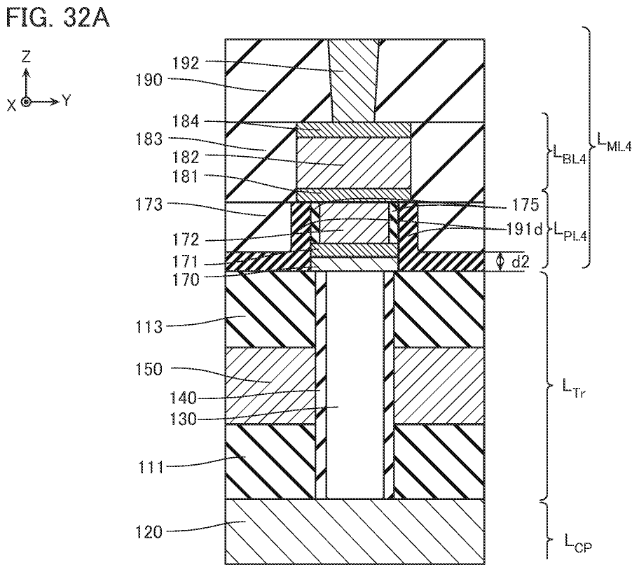

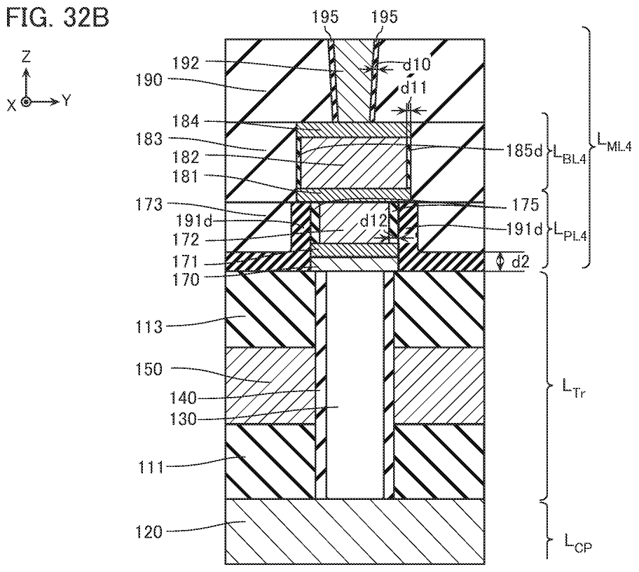

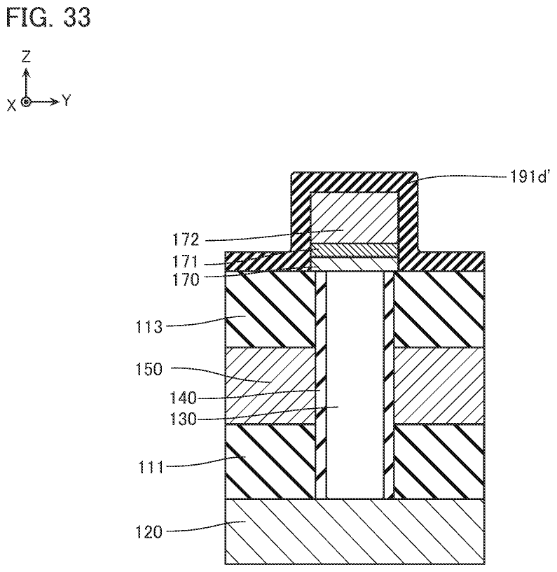

Next, with reference to FIG. 32A and FIG. 32B, a semiconductor device according to the fourth embodiment is described. FIG. 32A and FIG. 32B are schematic cross-sectional views illustrating a part of a configuration of the semiconductor device according to the embodiment. In the following description, the same reference numerals are attached to configurations similar to those in the first embodiment, and the explanation will be omitted.

The semiconductor device (FIG. 32A) according to the embodiment is basically configured similarly to the semiconductor device (FIG. 3A) according to the first embodiment. However, the semiconductor device according to the embodiment includes a wiring layer L_{ML4} (FIG. 32A) instead of the wiring layer L_{ML} (FIG. 3A). The wiring layer L_{ML4} is basically configured similarly to the wiring layer L_{ML}. However, the wiring layer L_{ML4} includes a plug layer L_{PL4} and a bit line layer L_{BL4} (FIG. 32A) instead of the plug layer L_{PL} and the bit line layer L_{BL} (FIG. 3A). Further, the wiring layer L_{ML4} is not provided with the metal oxide layer 191 on the upper surface of the insulating layer 190.

The plug layer L_{PL4} (FIG. 32A) is basically configured similarly to the plug layer L_{PL} (FIG. 3A). However, the plug layer L_{PL4} includes a metal oxide layer 191d (FIG. 32A) on the upper surface of the insulating layer 113 and outer peripheral surfaces of the conductive layer 170, the conductive layer 171, and the insulating layer 175.

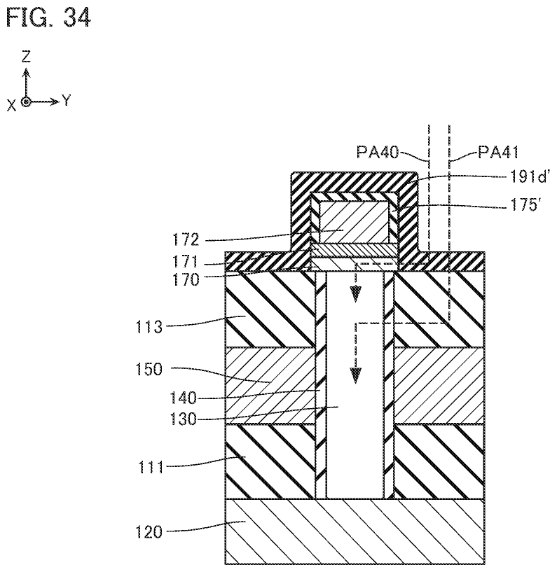

The metal oxide layer 191d functions as, for example, a layer to enhance the oxygen introduction efficiency to the semiconductor layer 130 in the first oxidation process (FIG. 34). Further, the metal oxide layer 191d functions as a layer to avoid reduction of the semiconductor layer 130 (occurrence of deoxygenation (O)) due to a reducing gas, such as hydrogen (H), used in the process of forming the wiring layer L_{UL} (FIG. 2).

The metal oxide layer 191d contains, for example, a film having an element similar to that of the metal oxide layer 191 and a characteristic similar to that of the metal oxide layer 191.

The metal oxide layer 191d has a width d2 (FIG. 32A) in a thickness direction. The width d2 is, for example, 1 nm or more and 5 nm or less.

For example, as illustrated in FIG. 32A, the bit line layer L_{BLA} is basically configured similarly to the bit line layer L_{BL} (FIG. 3A). However, the bit line layer L_{BL4} is not provided with the insulating layer 185 (FIG. 3A) on both side surfaces of the conductive layer 182.

For example, as illustrated in FIG. 32B, the conductive layer 182 may include an insulating layer 185d on both side surfaces of the conductive layer 182. The insulating layer 185d contains, for example, a metallic element contained in the conductive layer 182 and oxygen (O). The insulating layer 185d may be, for example, a metal oxide, such as tungsten oxide (WO).

The insulating layer 185d has a width d11 in a thickness direction. The width d11 is smaller than the width d12 of the insulating layer 175 in its thickness direction.

### Manufacturing Method of Fourth Embodiment

Next, with reference to FIG. 33 to FIG. 36, a method of manufacturing the semiconductor device according to the fourth embodiment is described. FIG. 33 to FIG. 36 are schematic cross-sectional views for describing the method of manufacturing the semiconductor device according to the fourth embodiment.

The semiconductor device according to the embodiment is basically manufactured similarly to the semiconductor device according to the first embodiment. However, in the manufacturing method of the semiconductor device according to the embodiment, processes illustrated in FIG. 33 to FIG. 36 are performed next to the process corresponding to the process described with reference to FIG. 14.

For example, in the process illustrated in FIG. 33, a metal oxide layer 191d′ is formed on the upper surface of the insulating layer 113, outer peripheral surfaces of the conductive layer 170 and the conductive layer 171, and the outer peripheral surface and the upper surface of the conductive layer 172. The metal oxide layer 191d′ contains a material similar to that of the metal oxide layer 191d. This process is performed by, for example, CVD or ALD.

Next, for example, as illustrated in FIG. 34, the first oxidation process described above is performed in a state where the metal oxide layer 191d′ is exposed, thereby introducing oxygen to the semiconductor layer 130 through, for example, oxygen introduction paths PA40, PA41.

The oxygen introduction path PA40 is a path that is able to introduce oxygen (O) from the upper surface of the semiconductor layer 130 via the metal oxide layer 191d′, and via the conductive layer 170 of indium tin oxide (InSnO) or the like.

The oxygen introduction path PA41 is a path that is able to introduce oxygen (O) from the side surface of the semiconductor layer 130 via the metal oxide layer 191d′, and via the insulating layer 113 and the insulating layer 140 of silicon oxide (SiO₂) or the like.

Further, for example, as illustrated in FIG. 34, the outer peripheral surface and the upper surface of the conductive layer 172 are oxidized by the first oxidation process, thereby forming an insulating layer 175′. The insulating layer 175′ contains, for example, a material similar to that of the insulating layer 175.

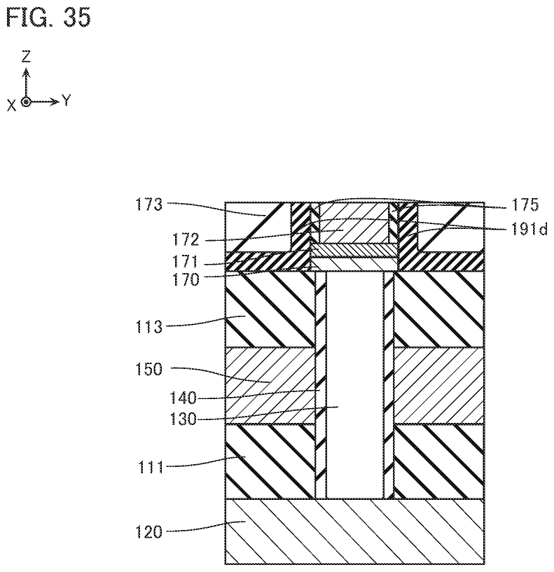

Next, for example, as illustrated in FIG. 35, a film of a material similar to that of the insulating layer 173 is formed on an upper surface of the metal oxide layer 191d′, and an upper surface of the film is removed and planarized until the conductive layer 172 is exposed, thereby forming the insulating layer 173, the insulating layer 175, and the metal oxide layer 191d. This process is performed by, for example, CVD and CMP.

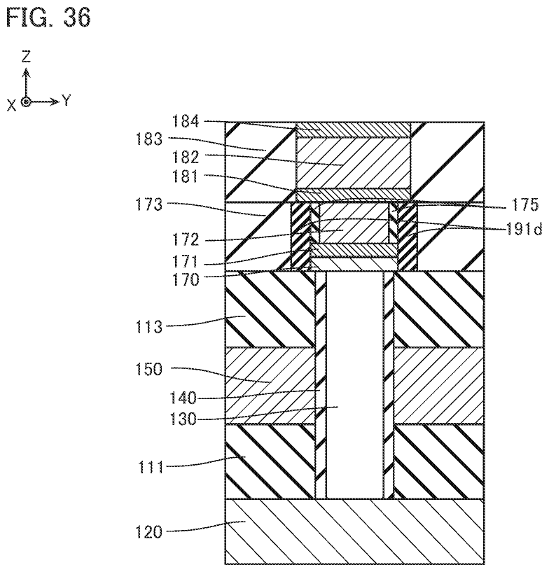

Next, for example, as illustrated in FIG. 36, at a position corresponding to the conductive layer 172, the conductive layer 181, the conductive layer 182, the conductive layer 184, and the insulating layer 183 are formed similarly to the process illustrated in FIG. 17.

Next, the insulating layer 190 is formed on the upper surfaces of the insulating layer 183 and conductive layer 184, an opening, which extends in the Z-direction and penetrates the insulating layer 190 to expose the conductive layer 184, is formed, and the conductive layer 192 is formed inside the opening. This process is performed by, for example, RIE, CVD, and CMP.

Next, the wiring layer L_{UL} (FIG. 2) is formed above the insulating layer 190, thus manufacturing the semiconductor device according to the fourth embodiment.

In these processes, the insulating layer 185d (FIG. 32B) may be formed on both side surfaces of the conductive layer 182. For example, the conductive layer 182 is in contact with the insulating layer 183 containing oxygen (O), such as silicon oxide (SiO₂), thereby forming the insulating layer 185d.

### Effects

In the semiconductor device according to the embodiment, since the oxygen introduction paths PA40, PA41 (FIG. 34) from the metal oxide layer 191d to the semiconductor layer 130 are relatively short, the oxygen introduction efficiency in the first oxidation process can be enhanced.

Additionally, since the conductive layer 182 is formed after the first oxidation process, the side surface of the conductive layer 182 is not oxidized, and the wiring resistance value of the conductive layer 182 can be made relatively low.

Further, since the metal oxide layer 191d (FIG. 32A) widely covers above the transistor layer L_{Tr}, similarly to the manufacturing method of the semiconductor device according to the first embodiment, it can be avoided that the reducing gas, such as hydrogen (H), reaches the semiconductor layer 130 in the formation of the wiring layer L_{UL}, and thus the deterioration of the switching characteristic of the select transistor ST (FIG. 1) can be avoided.

### Modification 1 of Fourth Embodiment

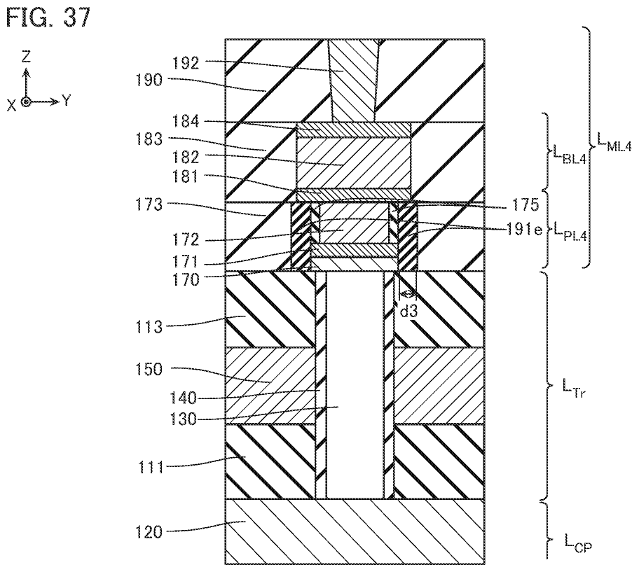

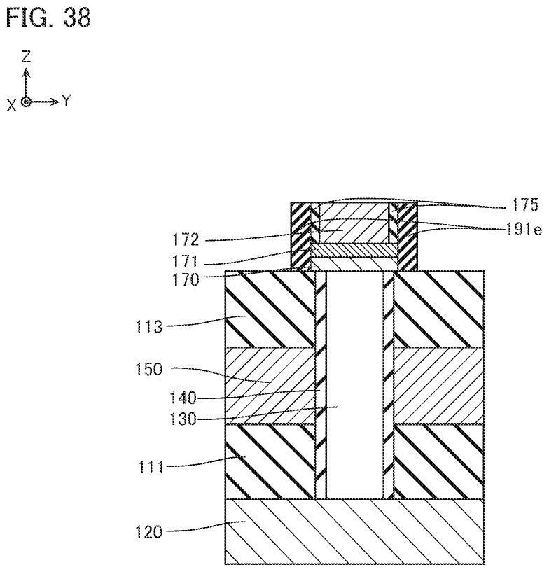

Next, with reference to FIG. 37, the modification 1 of the semiconductor device according to the fourth embodiment is described. FIG. 37 is a schematic cross-sectional view illustrating a part of a configuration of the semiconductor device according to the modification.

The semiconductor device according to the modification is basically configured similarly to the semiconductor device (FIG. 32A) according to the fourth embodiment. However, the semiconductor device (FIG. 37) according to the modification is not provided with the metal oxide layer 191d, but includes a metal oxide layer 191e. The metal oxide layer 191e is disposed on outer peripheral surfaces of the conductive layer 170, the conductive layer 171, and the insulating layer 175.

The metal oxide layer 191e functions as, for example, a layer to improve an oxygen supply efficiency to the semiconductor layer 130 in the first oxidation process (FIG. 34).

The metal oxide layer 191e contains, for example, a film having an element similar to that of the metal oxide layer 191 and a characteristic similar to that of the metal oxide layer 191.

The metal oxide layer 191e has a width d3 (FIG. 37) in a thickness direction. The width d3 is, for example, 1 nm or more and 5 nm or less.

### Manufacturing Method of Modification 1 of Fourth Embodiment

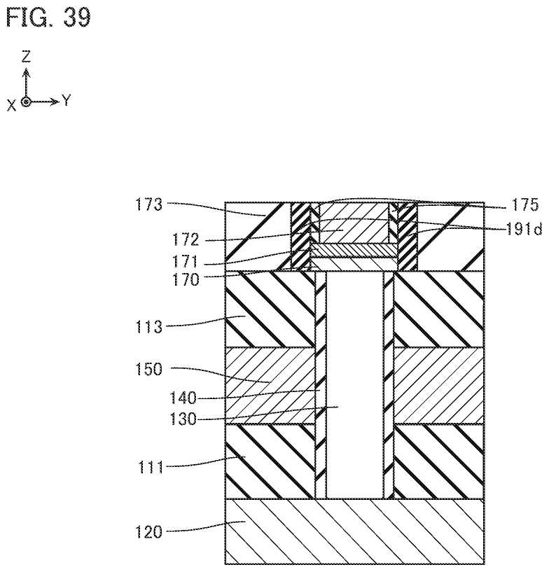

Next, with reference to FIG. 38 and FIG. 39, a method of manufacturing the semiconductor device according to the modification 1 of the fourth embodiment is described. FIG. 38 and FIG. 39 are schematic cross-sectional views for describing the method of manufacturing the semiconductor device according to the modification.

The semiconductor device according to the modification is basically manufactured similarly to the semiconductor device according to the fourth embodiment. However, in the manufacturing method of the semiconductor device according to the modification, processes illustrated in FIG. 38 and FIG. 39 are performed instead of the process described with reference to FIG. 35.

For example, in the process illustrated in FIG. 38, a part of the metal oxide layer 191d′ disposed on the upper surfaces of the insulating layer 113 and the insulating layer 175′ and a part of the insulating layer 175′ disposed on the upper surface of the conductive layer 172 are removed from the structure illustrated in FIG. 34, thereby forming the insulating layer 175 and the metal oxide layer 191e. This process is performed by, for example, RIE.

Next, for example, as illustrated in FIG. 39, a film of a material similar to that of the insulating layer 173 is formed on an upper surface of the structure illustrated in FIG. 38, and an upper surface of the film is removed and planarized until the conductive layer 172 is exposed, thereby forming the insulating layer 173. This process is performed by, for example, CVD and CMP.

### Modification 2 of Fourth Embodiment

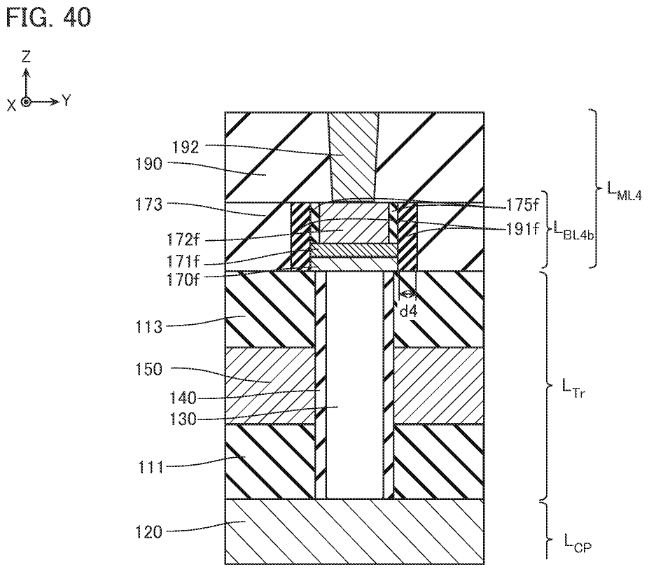

Next, with reference to FIG. 40, the modification 2 of the semiconductor device according to the fourth embodiment is described. FIG. 40 is a schematic cross-sectional view illustrating a part of a configuration of the semiconductor device according to the modification.

The semiconductor device according to the modification is basically configured similarly to the semiconductor device (FIG. 37) according to the modification 1 of the fourth embodiment. However, in the semiconductor device according to the modification, the wiring layer L_{ML4} is not provided with the plug layer L_{PL4} (FIG. 37). Further, the wiring layer L_{ML4} includes a bit line layer L_{BL4b} (FIG. 40) instead of the bit line layer L_{BL4} (FIG. 37).

For example, as illustrated in FIG. 40, the bit line layer L_{BL4b} includes a conductive layer 170f, a conductive layer 171f, and a conductive layer 172f and an insulating layer 175f disposed in the order on the upper surface of the transistor layer L_{Tr} at positions corresponding to the semiconductor layers 130. Further, for example, as illustrated in FIG. 40, the bit line layer L_{BL4b} includes a metal oxide layer 191f disposed on both side surfaces of the conductive layer 170f, the conductive layer 171f, and the insulating layer 175f.

Each of the conductive layer 170f, the conductive layer 171f, and the conductive layer 172f is electrically connected to a plurality of the semiconductor layers 130 arranged in the X-direction. The insulating layer 175f is disposed at a surface on the Y-direction positive side and a surface on the Y-direction negative side of the conductive layer 172f.

The structure including the conductive layer 170f, the conductive layer 171f, the conductive layer 172f, the insulating layer 175f, and the metal oxide layer 191f extends in the X-direction, for example, as illustrated in FIG. 40, and a plurality of the structures are disposed to be arranged in the Y-direction. The conductive layer 170f, the conductive layer 171f, and the conductive layer 172f function as, for example, source electrodes of the plurality of select transistors ST arranged in the X-direction and the bit lines BL (FIG. 1) of the memory cell array MCA. Between these structures arranged in the Y-direction, the insulating layer 173 is disposed.

The conductive layer 170f, the conductive layer 171f, the conductive layer 172f, and the insulating layer 175f contain, for example, materials similar to those of the conductive layer 170, the conductive layer 171, the conductive layer 172, and the insulating layer 175 (FIG. 3A), respectively.

The metal oxide layer 191f functions as, for example, a layer to enhance the oxygen introduction efficiency to the semiconductor layer 130 in the first oxidation process (FIG. 34).

The metal oxide layer 191f contains, for example, a film having an element similar to that of the metal oxide layer 191 and a characteristic similar to that of the metal oxide layer 191.

The metal oxide layer 191f has a width d4 (FIG. 40) in a thickness direction. The width d4 is, for example, 1 nm or more and 5 nm or less.

### Modification 3 of Fourth Embodiment

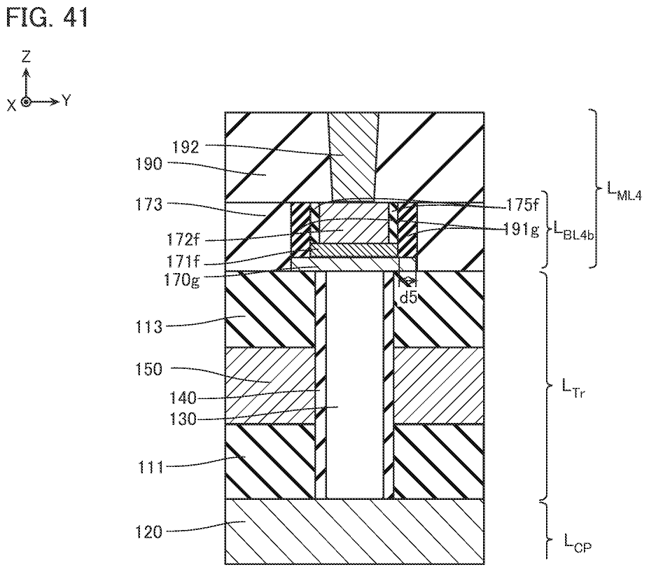

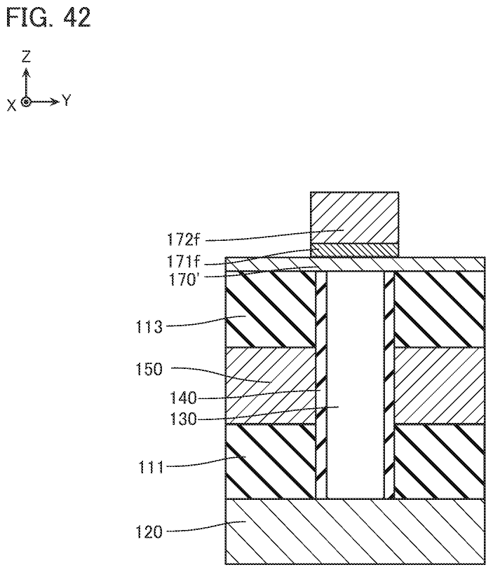

Next, with reference to FIG. 41, the modification 3 of the semiconductor device according to the fourth embodiment is described. FIG. 41 is a schematic cross-sectional view illustrating a part of a configuration of the semiconductor device according to the modification.

The semiconductor device according to the modification is basically configured similarly to the semiconductor device (FIG. 40) according to the modification 2 of the fourth embodiment. However, the semiconductor device according to the modification includes a conductive layer 170g and a metal oxide layer 191g instead of the conductive layer 170f and the metal oxide layer 191f.

The conductive layer 170g is basically disposed similarly to the conductive layer 170f. However, the metal oxide layer 191g is not disposed on both side surfaces of the conductive layer 170g in the Y-direction.

The metal oxide layer 191g is disposed on, for example, both side surfaces in the Y-direction of the conductive layer 171f, and both side surfaces on sides far from the conductive layer 172f of the insulating layer 175f.

The metal oxide layer 191g functions as, for example, a layer to enhance the oxygen introduction efficiency to the semiconductor layer 130 in the first oxidation process (FIG. 34).

The metal oxide layer 191g contains, for example, a film having an element similar to that of the metal oxide layer 191 and a characteristic similar to that of the metal oxide layer 191.

The metal oxide layer 191g has a width d5 (FIG. 41) in a thickness direction. The width d5 is, for example, 1 nm or more and 5 nm or less.

### Manufacturing Method of Modification 3 of Fourth Embodiment

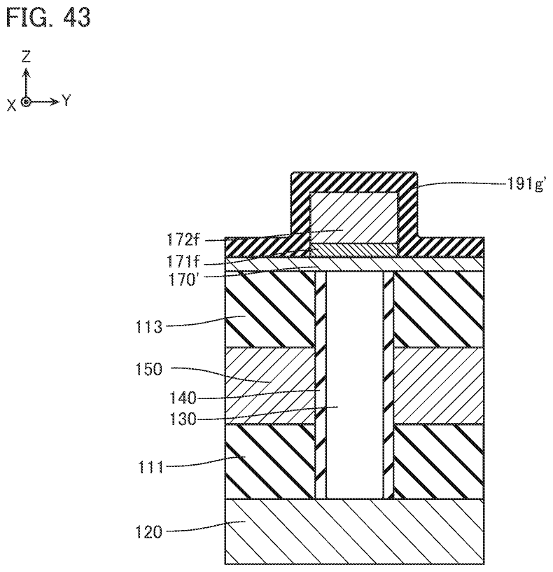

Next, with reference to FIG. 42 to FIG. 46, a method of manufacturing the semiconductor device according to the modification 3 of the fourth embodiment is described. FIG. 42 to FIG. 46 are schematic cross-sectional views for describing the method of manufacturing the semiconductor device according to the modification 3 of the fourth embodiment.

The semiconductor device according to the modification is basically manufactured similarly to the semiconductor device according to the first embodiment. However, in the manufacturing method of the semiconductor device according to the modification, processes illustrated in FIG. 42 to FIG. 46 are performed next to the process described with reference to FIG. 13.

For example, in a process illustrated in FIG. 42, a mask material is formed at a position corresponding to the conductive layer 171f and the conductive layer 172f by photolithography or the like, and the part not coated with the mask material is removed to form the conductive layer 171f and the conductive layer 172f. This process is performed by, for example, RIE. Note that in this process, processing of the conductive layer 170′ like the process illustrated in FIG. 14 is not performed.

Next, for example, as illustrated in FIG. 43, a metal oxide layer 191g′ is formed on an upper surface of the conductive layer 170′, side surfaces of the conductive layer 171f, and an outer peripheral surface and an upper surface of the conductive layer 172f. The metal oxide layer 191g′ contains a material similar to that of the metal oxide layer 191g. This process is performed by, for example, CVD or ALD.

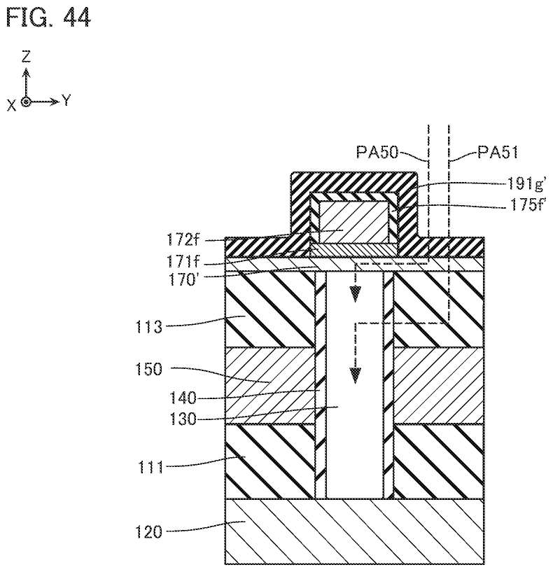

Next, for example, as illustrated in FIG. 44, the first oxidation process described above is performed in a state where the metal oxide layer 191g′ is exposed, thereby introducing oxygen to the semiconductor layer 130 through, for example, oxygen introduction paths PA50, PA51.

The oxygen introduction path PA50 is a path that is able to introduce oxygen (O) from the upper surface of the semiconductor layer 130 via the metal oxide layer 191g′, and via the conductive layer 170′ of indium tin oxide (InSnO) or the like.

The oxygen introduction path PA51 is a path that is able to introduce oxygen (O) from the side surface of the semiconductor layer 130 via the metal oxide layer 191g′, via the conductive layer 170′, and the insulating layer 113 and the insulating layer 140 of silicon oxide (SiO₂) or the like.

Further, for example, as illustrated in FIG. 44, the outer peripheral surface and the upper surface of the conductive layer 172f are oxidized by the first oxidation process, thereby forming an insulating layer 175f′. The insulating layer 175f′ contains, for example, a material similar to that of the insulating layer 175f.

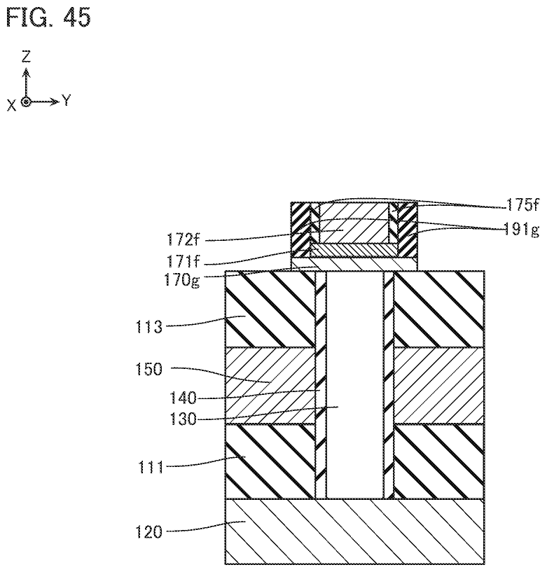

Next, for example, as illustrated in FIG. 45, an upper surface of the structure illustrated in FIG. 44 is removed to form the insulating layer 175f and the metal oxide layer 191g. This process is performed by, for example, RIE.

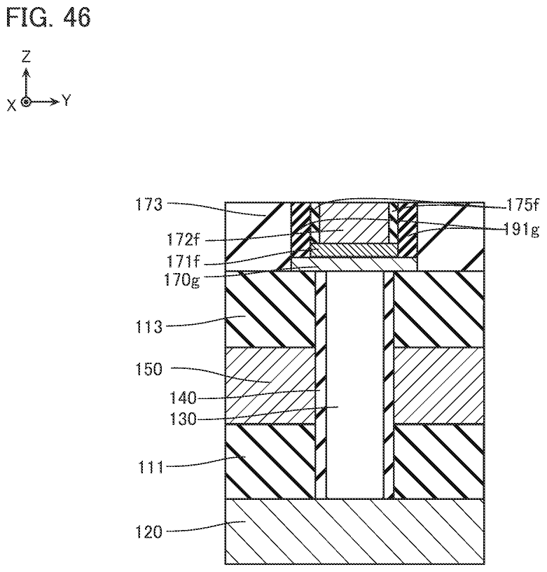

Next, for example, as illustrated in FIG. 46, a film of a material similar to that of the insulating layer 173 is formed on an upper surface of the structure illustrated in FIG. 45, and an upper surface of the film is removed and planarized until the conductive layer 172f is exposed, thereby forming the insulating layer 173. This process is performed by, for example, CVD and CMP.

Next, the insulating layer 190 and the conductive layer 192 are formed on an upper surface of the structure illustrated in FIG. 46, and the wiring layer L_{UL} (FIG. 2) is formed above the insulating layer 190, thus manufacturing the semiconductor device according to the modification 3 of the fourth embodiment.

### Fifth Embodiment

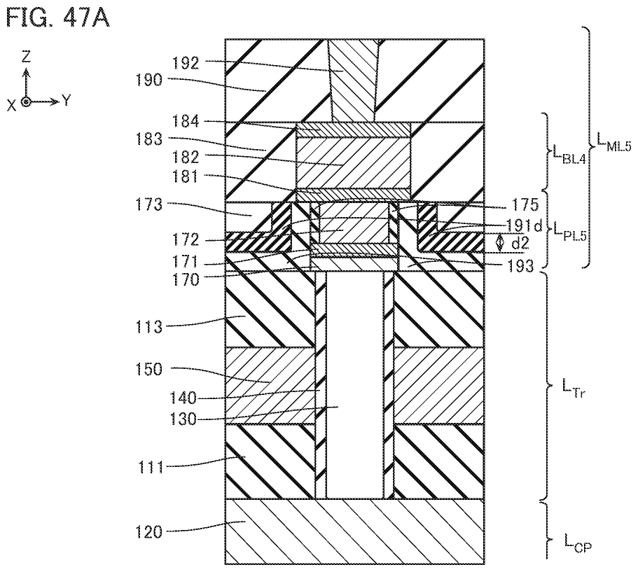

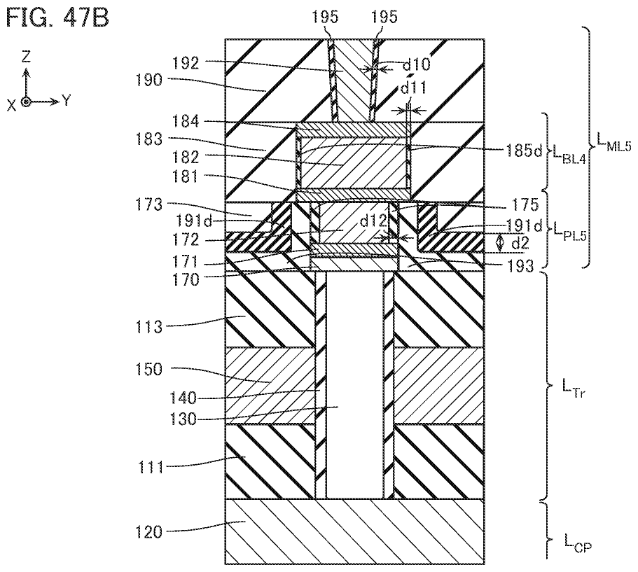

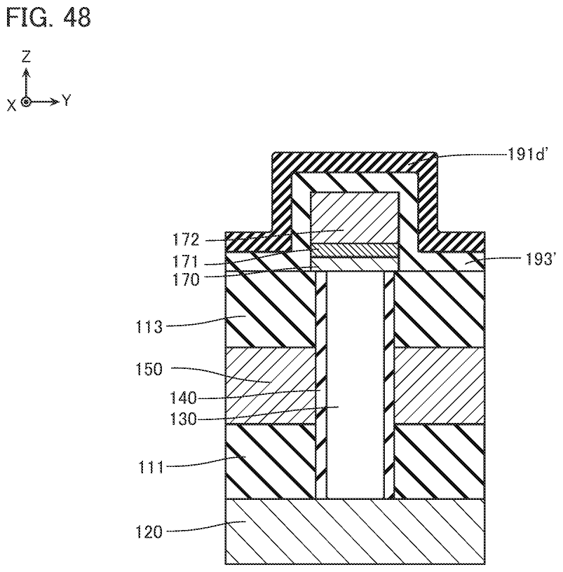

Next, with reference to FIG. 47A and FIG. 47B, a semiconductor device according to the fifth embodiment is described. FIG. 47A and FIG. 47B are schematic cross-sectional views illustrating a part of a configuration of the semiconductor device according to the embodiment. In the following description, the same reference numerals are attached to configurations similar to those in the fourth embodiment, and the explanation will be omitted.

The semiconductor device (FIG. 47A) according to the embodiment is basically configured similarly to the semiconductor device (FIG. 32A) according to the fourth embodiment. However, the semiconductor device according to the embodiment includes a wiring layer L_{ML5} (FIG. 47A) instead of the wiring layer L_{ML4} (FIG. 32A). The wiring layer L_{ML5} is basically configured similarly to the wiring layer L_{ML4}. However, the wiring layer L_{ML5} includes a plug layer L_{PL5} instead of the plug layer L_{PL4}.

The plug layer L_{PL5} (FIG. 47A) is basically configured similarly to the plug layer L_{PL4} (FIG. 32A). However, the plug layer L_{PL5} includes an insulating layer 193 of silicon oxide (SiO₂) or the like between the insulating layer 113 and the metal oxide layer 191d, and between the conductive layer 170, the conductive layer 171, and the insulating layer 175 and the metal oxide layer 191d.

Similarly to the fourth embodiment, the conductive layer 182 may include the insulating layer 185d on both side surfaces of the conductive layer 182, for example, as illustrated in FIG. 47B.

### Manufacturing Method of Fifth Embodiment

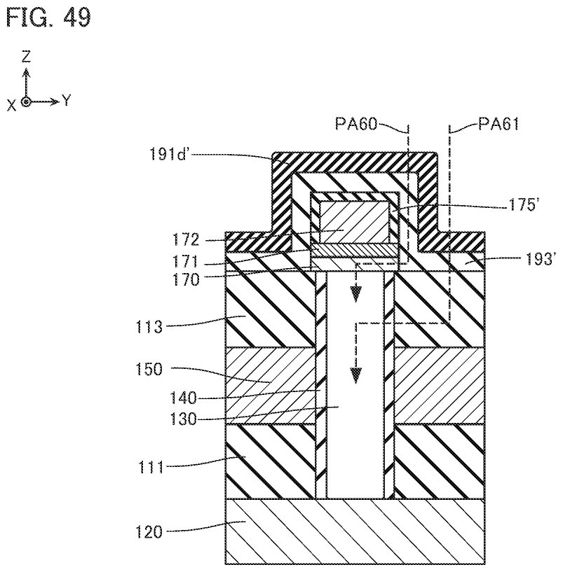

Next, with reference to FIG. 48 to FIG. 51, a method of manufacturing the semiconductor device according to the fifth embodiment is described. FIG. 48 to FIG. 51 are schematic cross-sectional views for describing the method of manufacturing the semiconductor device according to the fifth embodiment.

The semiconductor device according to the embodiment is basically manufactured similarly to the semiconductor device according to the first embodiment. However, in the manufacturing method of the semiconductor device according to the embodiment, processes illustrated in FIG. 48 to FIG. 51 are performed next to the process corresponding to the process described with reference to FIG. 14.

For example, in the process illustrated in FIG. 48, an insulating layer 193′ and a metal oxide layer 191d′ are formed in the order on the upper surface of the insulating layer 113, outer peripheral surfaces of the conductive layer 170 and the conductive layer 171, and the outer peripheral surface and the upper surface of the conductive layer 172. The insulating layer 193′ contains, for example, a material similar to that of the insulating layer 193. This process is performed by, for example, CVD or ALD.

Next, for example, as illustrated in FIG. 49, the first oxidation process described above is performed in a state where the metal oxide layer 191d′ is exposed, thereby introducing oxygen to the semiconductor layer 130 through, for example, oxygen introduction paths PA60, PA61.

The oxygen introduction path PA60 is a path that is able to introduce oxygen (O) from the upper surface of the semiconductor layer 130 via the metal oxide layer 191d′, via the insulating layer 193′ of silicon oxide (SiO₂) or the like, and via the conductive layer 170 of indium tin oxide (InSnO) or the like.

The oxygen introduction path PA61 is a path that is able to introduce oxygen (O) from the side surface of the semiconductor layer 130 via the metal oxide layer 191d′, and via the insulating layer 193′, the insulating layer 113, and the insulating layer 140 of silicon oxide (SiO₂) or the like.

Further, for example, as illustrated in FIG. 49, the outer peripheral surface and the upper surface of the conductive layer 172 are oxidized by the first oxidation process, thereby forming an insulating layer 175′. The insulating layer 175′ contains, for example, a material similar to that of the insulating layer 175.

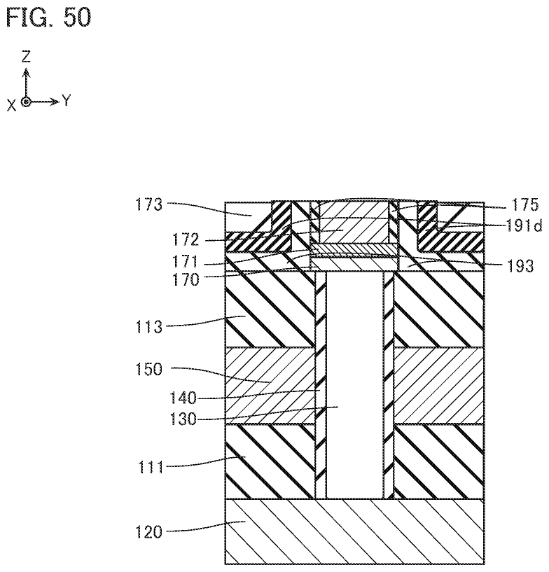

Next, for example, as illustrated in FIG. 50, a film of a material similar to that of the insulating layer 173 is formed on an upper surface of the metal oxide layer 191d′, and an upper surface of the film is removed and planarized until the conductive layer 172 is exposed, thereby forming the insulating layer 173, the insulating layer 175, the metal oxide layer 191d and the insulating layer 193. This process is performed by, for example, CVD and CMP.

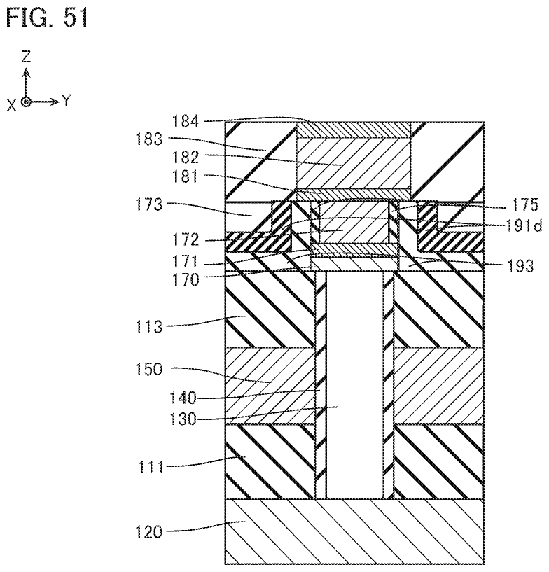

Next, for example, as illustrated in FIG. 51, at a position corresponding to the conductive layer 172, the conductive layer 181, the conductive layer 182, the conductive layer 184, and the insulating layer 183 are formed similarly to the process illustrated in FIG. 17.

Next, the insulating layer 190 is formed on the upper surfaces of the insulating layer 183 and conductive layer 184, an opening, which extends in the Z-direction and penetrates the insulating layer 190 to expose the conductive layer 184, is formed, and the conductive layer 192 is formed inside the opening. This process is performed by, for example, RIE, CVD, and CMP.

Next, the wiring layer L_{UL} (FIG. 2) is formed above the insulating layer 190, thus manufacturing the semiconductor device according to the fifth embodiment.

In these processes, the insulating layer 185d (FIG. 47B) may be formed on both side surfaces of the conductive layer 182. For example, the conductive layer 182 is in contact with the insulating layer 183 containing oxygen (O), such as silicon oxide (SiO₂), thereby forming the insulating layer 185d.

### Effects

In the semiconductor device according to the embodiment, since the insulating layer 193′ of silicon oxide (SiO₂) or the like in contact with the metal oxide layer 191d allows oxygen introduction to the semiconductor layer 130 through especially the path, such as an oxygen introduction path PA60 (FIG. 49), the oxygen introduction efficiency in the first oxidation process can be enhanced.

Additionally, since the conductive layer 182 is formed after the first oxidation process, the side surface of the conductive layer 182 is not oxidized, and the wiring resistance value of the conductive layer 182 can be made relatively low.

Further, since the metal oxide layer 191d (FIG. 47A) widely covers above the transistor layer L_{Tr}, similarly to the manufacturing method of the semiconductor device according to the first embodiment, it can be avoided that the reducing gas, such as hydrogen (H), reaches the semiconductor layer 130 in the formation of the wiring layer L_{UL}, and thus the deterioration of the switching characteristic of the select transistor ST (FIG. 1) can be avoided.

### Modification 1 of Fifth Embodiment

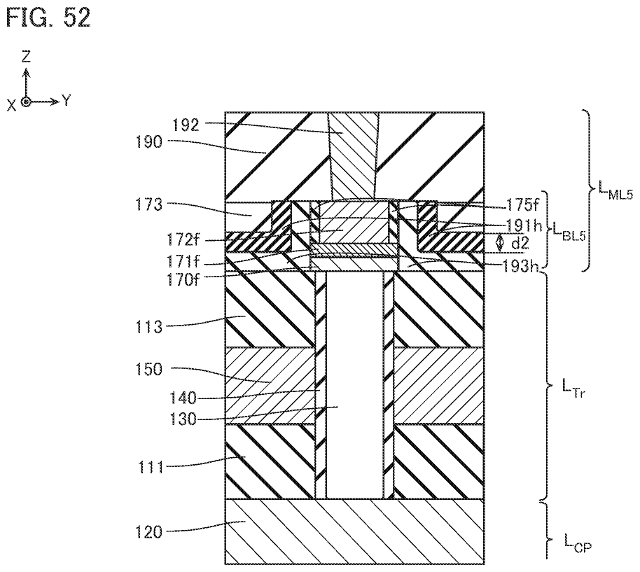

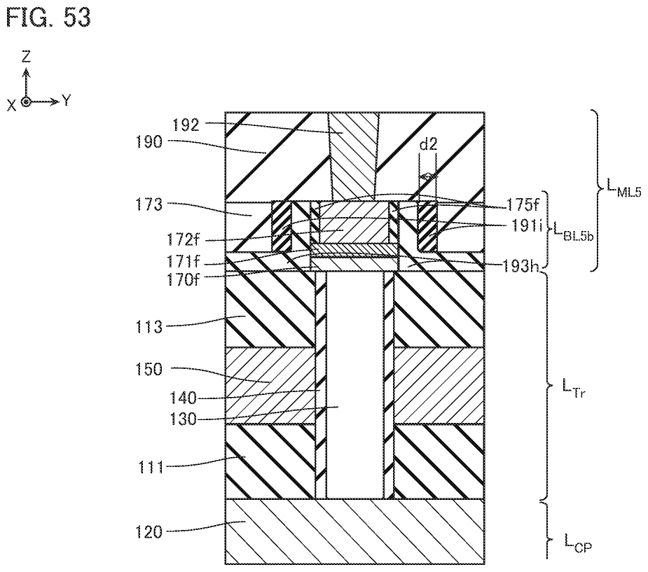

Next, with reference to FIG. 52, the modification 1 of the semiconductor device according to the fifth embodiment is described. FIG. 52 is a schematic cross-sectional view illustrating a part of a configuration of the semiconductor device according to the modification.

The semiconductor device according to the modification is basically configured similarly to the semiconductor device (FIG. 47A) according to the fifth embodiment. However, in the semiconductor device according to the modification, the wiring layer L_{ML5} is not provided with the plug layer L_{PL5} (FIG. 47A). Further, the wiring layer L_{ML5} includes a bit line layer L_{BL5} (FIG. 52) instead of the bit line layer L_{BL4} (FIG. 47A).

The bit line layer L_{BL5} (FIG. 52) is basically configured similarly to the bit line layer L_{BL4b} (FIG. 40). However, the bit line layer L_{BL5} includes a metal oxide layer 191h instead of the metal oxide layer 191f. Further, the bit line layer L_{BL5} includes an insulating layer 193h of silicon oxide (SiO₂) or the like between the insulating layer 113 and the metal oxide layer 191h, and between the conductive layer 170f, the conductive layer 171f, and the insulating layer 175f and the metal oxide layer 191h.

The metal oxide layer 191h contains, for example, a film having an element similar to that of the metal oxide layer 191 and a characteristic similar to that of the metal oxide layer 191.

The metal oxide layer 191h has a width d2 (FIG. 52) in a thickness direction similar to that of the metal oxide layer 191d (FIG. 47A).

### Modification 2 of Fifth Embodiment

Next, with reference to FIG. 53, the modification 2 of the semiconductor device according to the fifth embodiment is described. FIG. 53 is a schematic cross-sectional view illustrating a part of a configuration of the semiconductor device according to the modification.

The semiconductor device according to the modification is basically configured similarly to the semiconductor device (FIG. 52) according to the modification 1 of the fifth embodiment. However, the semiconductor device according to the modification includes a bit line layer L_{BL5b} (FIG. 53) instead of the bit line layer L_{BL5} (FIG. 52).

The bit line layer L_{BL5b} (FIG. 53) is basically configured similarly to the bit line layer L_{BL5} (FIG. 52). However, the bit line layer L_{BL5b} includes a metal oxide layer 191i instead of the metal oxide layer 191h. The metal oxide layer 191i is disposed on the Y-direction positive side and the Y-direction negative side of a structure including the conductive layer 170f, the conductive layer 171f, the conductive layer 172f, and the insulating layer 175f via a part of the insulating layer 193h.

The metal oxide layer 191i contains, for example, a film having an element similar to that of the metal oxide layer 191 and a characteristic similar to that of the metal oxide layer 191.

The metal oxide layer 191i has a width d2 in a thickness direction similar to that of the metal oxide layer 191d (FIG. 47A).

### Sixth Embodiment

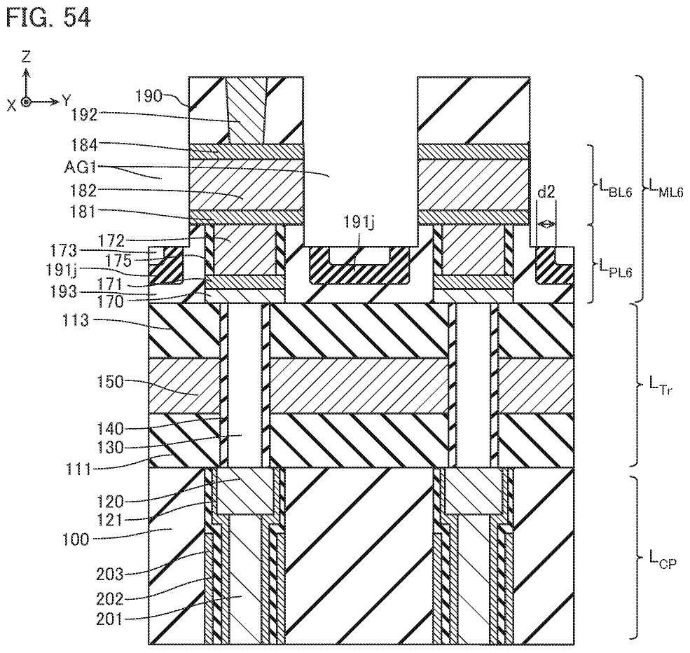

Next, with reference to FIG. 54, a semiconductor device according to the sixth embodiment is described. FIG. 54 is a schematic cross-sectional view illustrating a part of a configuration of the semiconductor device according to the embodiment. In the following description, the same reference numerals are attached to configurations similar to those in the fifth embodiment, and the explanation will be omitted.

The semiconductor device (FIG. 54) according to the embodiment is basically configured similarly to the semiconductor device (FIG. 47A) according to the fifth embodiment. However, the semiconductor device according to the embodiment includes a wiring layer L_{ML6} (FIG. 54) instead of the wiring layer L_{ML5} (FIG. 47A). The wiring layer L_{ML6} is basically configured similarly to the wiring layer L_{ML5}. However, the wiring layer L_{ML6} includes a bit line layer L_{BL6} and a plug layer L_{PL6} (FIG. 54) instead of the bit line layer L_{BL4} and the plug layer L_{PL5} (FIG. 47A).

The bit line layer L_{BL6} (FIG. 54) is basically configured similarly to the bit line layer L_{BL4} (FIG. 47A). However, the bit line layer L_{BL6} is provided with a cavity AG1 between the adjacent two conductive layers 181, conductive layers 182, and conductive layers 184.

The plug layer L_{PL6} (FIG. 54) is basically configured similarly to the plug layer L_{PL5} (FIG. 47A). However, the plug layer L_{PL6} includes a metal oxide layer 191j instead of the metal oxide layer 191d. A part of the cavity AG1 is provided above the metal oxide layer 191j.

The cavity AG1 means what is called a space surrounded by solid materials disposed around the part provided with the cavity AG1, and the part provided with the cavity AG1 does not contain any of the solid materials. The cavity AG1 is a space containing, for example, air consisting of a mixture of a plurality of gases, such as nitrogen, oxygen, and a noble gas. The cavity AG1 may be degassed so as not to contain any gas.

The metal oxide layer 191j contains, for example, a film having an element similar to that of the metal oxide layer 191 and a characteristic similar to that of the metal oxide layer 191.

The metal oxide layer 191j has a width d2 in a thickness direction similar to that of the metal oxide layer 191d (FIG. 47A).

### Manufacturing Method of Sixth Embodiment

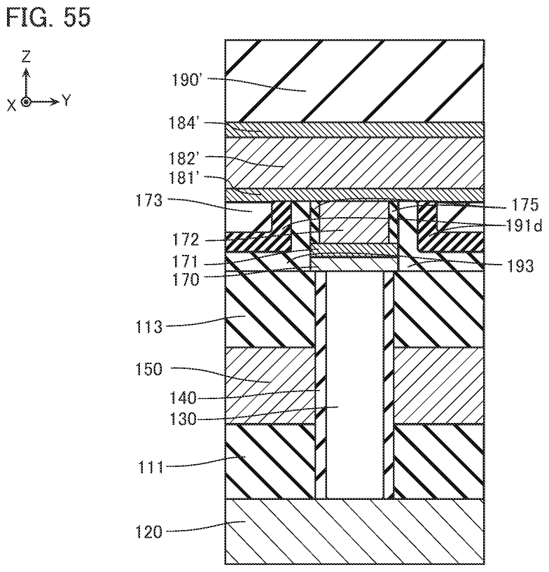

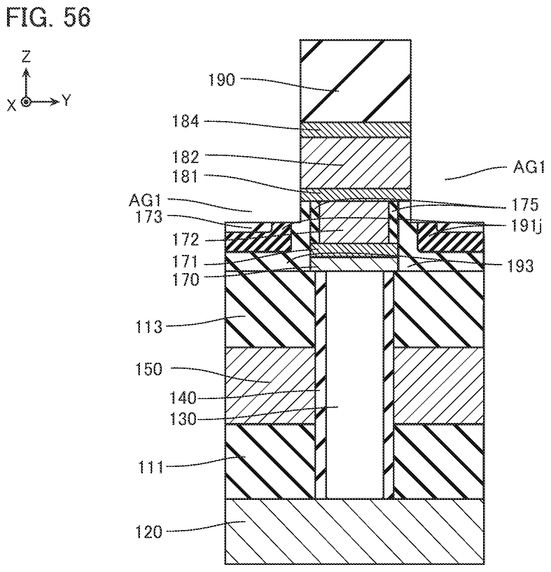

Next, with reference to FIG. 55 and FIG. 56, a method of manufacturing the semiconductor device according to the sixth embodiment is described. FIG. 55 and FIG. 56 are schematic cross-sectional views for describing the method of manufacturing the semiconductor device according to the sixth embodiment.

The semiconductor device according to the embodiment is basically manufactured similarly to the semiconductor device according to the fifth embodiment. However, in the manufacturing method of the semiconductor device according to the embodiment, processes illustrated in FIG. 55 and FIG. 56 are performed next to the process corresponding to the process described with reference to FIG. 50.

For example, in the process illustrated in FIG. 55, the conductive layer 181′, the conductive layer 182′, the conductive layer 184′, and an insulating layer 190′ of silicon oxide (SiO₂) or the like are formed in the order. This process is performed by, for example, CVD or ALD.

Next, for example, as illustrated in FIG. 56, the metal oxide layer 191d, the insulating layer 173, the conductive layer 181′, the conductive layer 182′, the conductive layer 184′, and the insulating layer 190′ are partially removed to form the cavity AG1, the metal oxide layer 191j, the conductive layer 181, the conductive layer 182, the conductive layer 184, and the insulating layer 190. This process is performed by, for example, RIE.

Next, the conductive layer 192 and the wiring layer L_{UL} (FIG. 2) are formed, thus manufacturing the semiconductor device according to the sixth embodiment.

### Other Embodiments

The semiconductor devices according to the first embodiment to the sixth embodiment have been described above. However, the semiconductor devices according to these embodiments are merely examples, and the specific configuration, operation, and the like are adjustable as necessary.

For example, in the above description, the example in which the capacitor Cap (FIG. 1) is connected to the select transistor ST (FIG. 1) is described. In this example, the shape, the structure, and the like of the capacitor Cap can be adjusted as necessary.

Additionally, in the above description, the example in which the capacitor Cap (FIG. 1) is employed as the memory portion connected to the select transistor ST (FIG. 1) is described. However, the memory portion need not be the capacitor Cap. For example, the memory portion may contain a ferroelectric material, a ferromagnet material, a chalcogen material such as GeSbTe, or another material and may store data using the characteristics of these materials. For example, in any of the structures described above, any of these materials may be contained in the insulating layer between the electrodes forming the capacitor Cap.

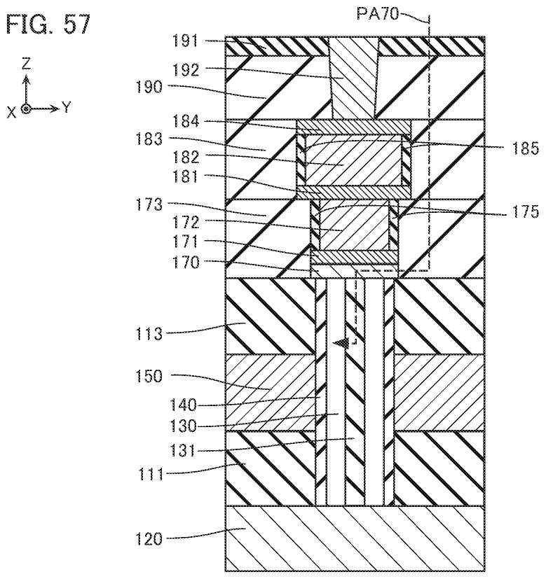

The above description shows an example where the semiconductor layer 130 that functions as the channel region of the select transistor ST (FIG. 1) extends in, for example, the Z-direction and has an approximately columnar shape. However, for example, as illustrated in FIG. 57, the semiconductor layer 130 may have an approximately cylindrical shape extending in the Z-direction. Further, an approximately columnar insulating layer 131 extending in the Z-direction may be disposed inside the semiconductor layer 130. The insulating layer 131 contains, for example, silicon oxide (SiO₂).

In an example illustrated in FIG. 57, the semiconductor layer 130 may be oxidized using an oxygen introduction path PA70 in the first oxidation process. The oxygen introduction path PA70 is a path that is able to introduce oxygen (O) from an inner side surface of the semiconductor layer 130 via the metal oxide layer 191, via the insulating layer 190, the insulating layer 183, and the insulating layer 173 of silicon oxide (SiO₂) or the like, via the conductive layer 170 of indium tin oxide (InSnO) or the like, and further via the insulating layer 131. With such an oxygen introduction path PA70, since oxygen (O) can be supplied also from the inside of the semiconductor layer 130 in the structure illustrated in FIG. 57, the oxygen supply efficiency to the semiconductor layer 130 can be more improved.

### Others

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor device comprising:
a substrate;
an oxide semiconductor layer spaced from the substrate in a first direction intersecting with a surface of the substrate;
a first wiring opposed to a part of the oxide semiconductor layer;
a gate insulating film disposed between the oxide semiconductor layer and the first wiring;
a second wiring electrically connected to one end in the first direction of the oxide semiconductor layer; and
a first insulating layer disposed on a surface on one side and a surface on the other side in a second direction intersecting with the first direction of the second wiring,
wherein
the second wiring contains a first metallic element, and
the first insulating layer contains the first metallic element and oxygen (O).

2. The semiconductor device according to claim 1, further comprising:
a metal oxide layer farther from the substrate than the oxide semiconductor layer,
wherein
the metal oxide layer contains at least one metallic element selected from the group consisting of aluminum (Al), hafnium (Hf), zirconium (Zr), lanthanum (La), yttrium (Y), titanium (Ti), nickel (Ni), zinc (Zn), indium (In), tin (Sn), gallium (Ga), and tungsten (W), and contains oxygen (O).

3. The semiconductor device according to claim 2, wherein the metal oxide layer is farther from the substrate than the second wiring.

4. The semiconductor device according to claim 2, wherein the metal oxide layer is disposed on the one side and the other side in the second direction of the second wiring.

5. The semiconductor device according to claim 1, further comprising:
a third wiring farther from the substrate than the second wiring,
wherein
a surface on the one side and a surface on the other side in the second direction of the third wiring is in contact with an insulating layer containing silicon (Si) and oxygen (O).

6. The semiconductor device according to claim 1, further comprising:
a third wiring farther from the substrate than the second wiring; and
a second insulating layer disposed on a surface on the one side and a surface on the other side of the third wiring in the second direction,
wherein
the third wiring contains a second metallic element,
the second insulating layer contains the second metallic element and oxygen (O), and
a film thickness of the first insulating layer in the second direction is larger than a film thickness of the second insulating layer in the second direction.

7. The semiconductor device according to claim 1, further comprising:
a first conductive layer connected to one end portion in the first direction of the oxide semiconductor layer, wherein the first conductive layer contains indium (In), tin (Sn), and oxygen (O).

8. The semiconductor device according to claim 1, further comprising:
a capacitor layer between the substrate and the oxide semiconductor layer,
wherein
the capacitor layer includes a capacitor structure electrically connected to the oxide semiconductor layer.

9. A semiconductor device comprising:
a substrate;
an oxide semiconductor layer spaced from the substrate in a first direction intersecting with a surface of the substrate;
a first wiring opposed to a part of the oxide semiconductor layer;
a gate insulating film disposed between the oxide semiconductor layer and the first wiring;
a second wiring electrically connected to one end in the first direction of the oxide semiconductor layer; and
a metal oxide layer farther from the substrate than the oxide semiconductor layer,
wherein
the metal oxide layer contains at least one metallic element selected from the group consisting of aluminum (Al), hafnium (Hf), zirconium (Zr), lanthanum (La), yttrium (Y), titanium (Ti), nickel (Ni), zinc (Zn), indium (In), tin (Sn), gallium (Ga), and tungsten (W), and contains oxygen (O).

10. The semiconductor device according to claim 9, wherein the metal oxide layer is farther from the substrate than the second wiring.

11. The semiconductor device according to claim 9, wherein the metal oxide layer is disposed on one side and the other side in a second direction intersecting with the first direction of the second wiring.

12. The semiconductor device according to claim 9, further comprising:
a first conductive layer connected to one end portion in the first direction of the oxide semiconductor layer, wherein the first conductive layer contains indium (In), tin (Sn), and oxygen (O).

13. The semiconductor device according to claim 9, further comprising:
a capacitor layer between the substrate and the oxide semiconductor layer,
wherein
the capacitor layer includes a capacitor structure electrically connected to the oxide semiconductor layer.

14. A method of manufacturing a semiconductor device, wherein
the semiconductor device includes:
a substrate;
an oxide semiconductor layer spaced from the substrate in a first direction intersecting with a surface of the substrate;
a first wiring opposed to a part of the oxide semiconductor layer, a gate insulating film disposed between the oxide semiconductor layer and the first wiring; and
a second wiring electrically connected to one end in the first direction of the oxide semiconductor layer, and
the method comprises:
forming the oxide semiconductor layer;
forming a metal oxide layer farther from the substrate than the oxide semiconductor layer; and
performing a first process in a state where the metal oxide layer is exposed, wherein
the first process includes at least one process selected from the group consisting of radical oxidation, formation of a film containing oxygen (O) by plasma CVD, and oxygen plasma ashing.

15. The method of manufacturing the semiconductor device according to claim 14, wherein
the metal oxide layer contains at least one metallic element selected from the group consisting of aluminum (Al), hafnium (Hf), zirconium (Zr), lanthanum (La), yttrium (Y), titanium (Ti), nickel (Ni), zinc (Zn), indium (In), tin (Sn), gallium (Ga), and tungsten (W), and contains oxygen (O).

16. The method of manufacturing the semiconductor device according to claim 14,
wherein
the semiconductor device further includes a first insulating layer disposed on a surface on one side and a surface on the other side in a second direction intersecting with the first direction of the second wiring,
the second wiring is formed before forming the metal oxide layer, and
the first insulating layer is formed by the first process.

17. The method of manufacturing the semiconductor device according to claim 14,
wherein
the second wiring is formed before forming the metal oxide layer, and
a conductive layer or an insulating layer is formed on the metal oxide layer.

18. The method of manufacturing the semiconductor device according to claim 14,
wherein
the second wiring is formed before forming the metal oxide layer,
the metal oxide layer is formed on one side and the other side in a second direction intersecting with the first direction of the second wiring, and
an insulating layer is formed on the metal oxide layer.

19. The method of manufacturing the semiconductor device according to claim 14,
wherein
the semiconductor device further includes a first conductive layer connected to one end portion in the first direction of the oxide semiconductor layer, and
the first conductive layer contains indium (In), tin (Sn), and oxygen (O).

20. The method of manufacturing the semiconductor device according to claim 14,
wherein
the metal oxide layer is removed after performing the first process.
